(19) United States
(12) Patent Application Publication
(10) Pub. No.: US 2023/0341641 A1
(43) Pub. Date: Oct. 26, 2023

(54) OPTICAL DEVICE AND BUMP ARRANGEMENT METHOD

(71) Applicant: Fujitsu Optical Components Limited, Kawasaki-shi (JP)

(72) Inventor: Takeshi MATSUMOTO, Ebina (JP)

(73) Assignee: Fujitsu Optical Components Limited, Kawasaki-shi (JP)

(21) Appl. No.: 18/178,134

(22) Filed: Mar. 3, 2023

(30) Foreign Application Priority Data
Apr. 26, 2022 (JP) 2022-072472

(51) Int. Cl. G02B 6/42

(52) U.S. Cl. CPC G02B 6/4267; G02B 6/4238; G02B 6/4245; G02B 6/4257

(57) ABSTRACT

An optical device includes a substrate that includes a substrate-side electrode, and a chip that includes N active layers and a chip-side electrode that is mounted on the substrate-side electrode. From among bumps that are disposed side by side with an Nth layer on both sides of a surface that is located opposite the Nth layer and that is included in the substrate-side electrode, bumps located at a position farther away from the center of gravity of all of the bumps are defined as first bumps, and bumps located at a position closer to the center of gravity are defined as second bumps. In at least one combination of the first bump and the second bump, the first bump and the second bump are arranged on the substrate-side electrode such that a distance between the first bump and the surface is longer than a distance between the second bump and the surface.

### CROSS-REFERENCE TO RELATED APPLICATION

This application is based upon and claims the benefit of priority of the prior Japanese Patent Application No. 2022-072472, filed on Apr. 26, 2022, the entire contents of which are incorporated herein by reference.

### FIELD

The embodiments discussed herein are related to an optical device and a bump arrangement method.

### BACKGROUND

In recent years, developments of silicon photonics are widely facilitated as an integrated optical device technology that implements small size and large capacity transceivers. Silicon that is used for silicon photonics is a semiconductor material having the feature of indirect transition and low luminous efficiency, and, as an optical gain medium, for example, a compound semiconductor element constituted of an InP-based semiconductor, or the like is included. There is a known hybrid integration optical device constructed by bonding a chip constituted of a compound semiconductor element of, for example, semiconductor laser, a semiconductor optical amplifier, or the like on a substrate, such as a silicon photonics substrate, provided with an optical waveguide by using solder bumps.

When a chip provided with an active layer included in the compound semiconductor element is mounted on the substrate provided with the optical waveguide, thermal compression bonding using the solder bumps is commonly used. However, in the case where the substrate and the chip are bonded by the solder bumps, the characteristic of the compound semiconductor element is degraded as a result of a stress applied from the solder bumps being applied to the active layer included in the compound semiconductor element. Furthermore, in the compound semiconductor element, if a temperature of the active layer is increased, the characteristic of the compound semiconductor element is decreased, an efficient heat dissipation characteristic exhibiting on the substrate side via the solder bump is important.

FIG. 41 is a schematic cross-sectional diagram illustrating an example of a conventional optical device. An optical device 100 illustrated in FIG. 41 includes a substrate 101 provided with a mounting groove 101A, and a chip 102 that has a built-in compound semiconductor element. The substrate 101 includes a substrate-side electrode 103 in the mounting groove 101A in order to mount the chip 102. The chip 102 includes an active layer 104 that has a stripe shape and that functions as an optical waveguide in the compound semiconductor element. Furthermore, the chip 102 includes a chip-side electrode 105 that is surface mounted on a bonding surface of the substrate-side electrode 103.

When a portion between the substrate-side electrode 103 included in the substrate 101 and the chip-side electrode 105 included in the chip 102 is bonded by a solder bump 106, the solder bump 106 is arranged only on the bonding surface of the substrate-side electrode 103 at a position opposite the active layer 104 included in the chip 102. Then, by bonding a portion between the substrate-side electrode 103 and the chip-side electrode 105 by the solder bump 106, the chip 102 is accordingly mounted on the substrate 101.

In the conventional optical device 100, the solder bump 106 is arranged only on the bonding surface of the substrate-side electrode 103 at the position opposite the active layer 104 included in the chip 102. Consequently, when compared to a case in which the solder bump 106 is arranged in a wide range of the bonding surface of the substrate-side electrode 103 on which the chip-side electrode 105 is mounted, the solder bump 106 is present only at the position immediately below the active layer 104, so that it is possible to ensure an efficient heat dissipation characteristic while suppressing the stress caused by thermal contraction of the solder bump 106.

FIG. 42 is a schematic cross-sectional diagram illustrating an example of a conventional optical device. An optical device 100A illustrated in FIG. 42 includes the substrate 101 provided with the mounting groove 101A, and the chip 102 that has a built-in compound semiconductor element. The substrate 101 includes two substrate-side electrodes 103A with a stripe shape in the mounting groove 101A that is used to mount therein the chip 102. The chip 102 has the single built-in active layer 104 with a stripe shape. The chip 102 includes the chip-side electrode 105 that is surface mounted on the bonding surface of the substrate-side electrode 103A.

The substrate 101 includes a plurality of bases 101B that are used to place thereon the chip 102. Furthermore, the two substrate-side electrodes 103A are arranged inside the mounting groove 101A so as to sandwich a region 101C that is included in the mounting groove 101A and that is located opposite the active layer 104 included in the chip 102.

The substrate 101 is constituted such that, the chip 102 is surface mounted on the substrate 101 by bonding a portion between the two substrate-side electrodes 103A and the chip-side electrode 105 by a solder bump 106A in a state in which the chip 102 is placed on the base 101B.

In the conventional optical device 100A, the two substrate-side electrodes 103A are arranged in the mounting groove 101A so as to sandwich the region 101C that is included in the substrate 101 and that is located opposite the active layer 104, i.e., the region 101C located immediately below the active layer 104. Consequently, it is possible to reduce the stress applied to the active layer 104 caused by the solder bump 106A.
Patent Document 1: Japanese Laid-open Patent Publication No. 2012-222336
Patent Document 2: Japanese Laid-open Patent Publication No. 2012-151324

However, in the conventional optical device 100 illustrated in FIG. 41, even though it is possible to ensure the heat dissipation characteristic, thermal stress produced caused by a difference between the thermal expansion coefficients of the compound semiconductor element and the substrate 101 is applied to the active layer 104 included in the compound semiconductor element via the solder bump 106. Consequently, the characteristic of the compound semiconductor element is accordingly degraded.

In addition, in the conventional optical device 100A illustrated in FIG. 42, it is possible to reduce the stress applied by the solder bump 106A; however, an optical characteristic of the compound semiconductor element due to a temperature rise of the active layer 104 included in the compound semiconductor element.

In other words, in the optical device, there is a need to ensure the heat dissipation characteristic while suppressing the effect of the thermal stress.

### SUMMARY

According to an aspect of an embodiment, an optical device includes a substrate and a chip. The substrate includes a substrate-side electrode. The chip includes N (N≥1) active layers with a stripe shape and a chip-side electrode that is mounted on the substrate-side electrode. From among bumps that are disposed side by side with an Nth active layer on both sides of a bonding surface that is located opposite the Nth active layer and that is included in the substrate-side electrode, bumps located at a position farther away from a position of the center of gravity of all of the bumps are defined as first bumps, and bumps located at a position closer to the position of the center of gravity are defined as second bumps. Further, in at least one combination of the first bump and the second bump, the first bump and the second bump are arranged on the substrate-side electrode such that a distance between the first bump and the bonding surface is longer than a distance between the second bump and the bonding surface.

The object and advantages of the invention will be realized and attained by means of the elements and combinations particularly pointed out in the claims.

It is to be understood that both the foregoing general description and the following detailed description are exemplary and explanatory and are not restrictive of the invention, as claimed.

### BRIEF DESCRIPTION OF DRAWINGS

FIG. 1 is a schematic plan view illustrating an example of an optical device according to a first embodiment;

FIG. 2 is a schematic plan view illustrating an example of a substrate;

FIG. 3 is a schematic cross-sectional diagram of the substrate taken along line A-A illustrated in FIG. 2;

FIG. 4 is a schematic plan view illustrating an example of a chip;

FIG. 5 is a schematic cross-sectional diagram of the chip taken along line B-B illustrated in FIG. 4;

FIG. 6 is a schematic cross-sectional diagram taken along line C-C illustrated in FIG. 1;

FIG. 7 is a schematic plan view illustrating an example of an optical device according to a second embodiment;

FIG. 8 is a schematic plan view illustrating an example of a substrate;

FIG. 9 is a schematic cross-sectional diagram of the substrate taken along line A1-A1 illustrated in FIG. 8;

FIG. 10 is a schematic plan view illustrating an example of a chip;

FIG. 11 is a schematic cross-sectional diagram of the chip taken along line B1-B1 illustrated in FIG. 10;

FIG. 12 is a schematic cross-sectional diagram taken along line C1-C1 illustrated in FIG. 7;

FIG. 13 is a schematic plan view illustrating an example of an optical device according to a third embodiment;

FIG. 14 is a schematic plan view illustrating an example of a substrate;

FIG. 15 is a schematic cross-sectional diagram of the substrate taken along line A2-A2 illustrated in FIG. 14;

FIG. 16 is a schematic cross-sectional diagram taken along line C2-C2 illustrated in FIG. 13;

FIG. 17 is a schematic plan view illustrating an example of an optical device according to a fourth embodiment;

FIG. 18 is a schematic plan view illustrating an example of a substrate;

FIG. 19 is a schematic cross-sectional diagram of the substrate taken along line A3-A3 illustrated in FIG. 18;

FIG. 20 is a schematic plan view illustrating an example of a chip;

FIG. 21 is a schematic cross-sectional diagram of the chip taken along line B3-B3 illustrated in FIG. 20;

FIG. 22 is a schematic cross-sectional diagram taken along line C3-C3 illustrated in FIG. 17;

FIG. 23 is a schematic plan view illustrating an example of an optical device according to a fifth embodiment;

FIG. 24 is a schematic plan view illustrating an example of a substrate;

FIG. 25 is a schematic cross-sectional diagram taken along line A4-A4 of the substrate illustrated in FIG. 24;

FIG. 26 is a schematic plan view illustrating an example of a chip;

FIG. 27 is a schematic cross-sectional diagram of the chip taken along line B4-B4 illustrated in FIG. 26;

FIG. 28 is a schematic cross-sectional diagram taken along line C4-C4 illustrated in FIG. 23;

FIG. 29 is a schematic plan view illustrating an example of an optical device according to a sixth embodiment;

FIG. 30 is a schematic plan view illustrating an example of a substrate;

FIG. 31 is a schematic cross-sectional diagram of the substrate taken along line A5-A5 illustrated in FIG. 30;

FIG. 32 is a schematic plan view illustrating an example of a chip;

FIG. 33 is a schematic cross-sectional diagram of the chip taken along line B5-B5 illustrated in FIG. 32;

FIG. 34 is a schematic cross-sectional diagram taken along line C5-C5 illustrated in FIG. 29;

FIG. 35 is a schematic plan view illustrating an example of an optical device according to a seventh embodiment;

FIG. 36 is a schematic plan view illustrating an example of a substrate;

FIG. 37 is a schematic cross-sectional diagram of the substrate taken along line A6-A6 illustrated in FIG. 36;

FIG. 38 is a schematic plan view illustrating an example of a chip;

FIG. 39 is a schematic cross-sectional diagram of a chip taken along line B6-B6 illustrated in FIG. 38;

FIG. 40 is a schematic cross-sectional diagram taken along line C6-C6 illustrated in FIG. 35;

FIG. 41 is a schematic cross-sectional diagram illustrating an example of a conventional optical device; and

FIG. 42 is a schematic cross-sectional diagram illustrating an example of a conventional optical device.

### DESCRIPTION OF EMBODIMENTS

Preferred embodiments of the present invention will be explained with reference to accompanying drawings. Furthermore, the present invention is not limited to the embodiments. In addition, the embodiments described below may also be used in any appropriate combination as long as the embodiments do not conflict with each other.

### (a) First Embodiment

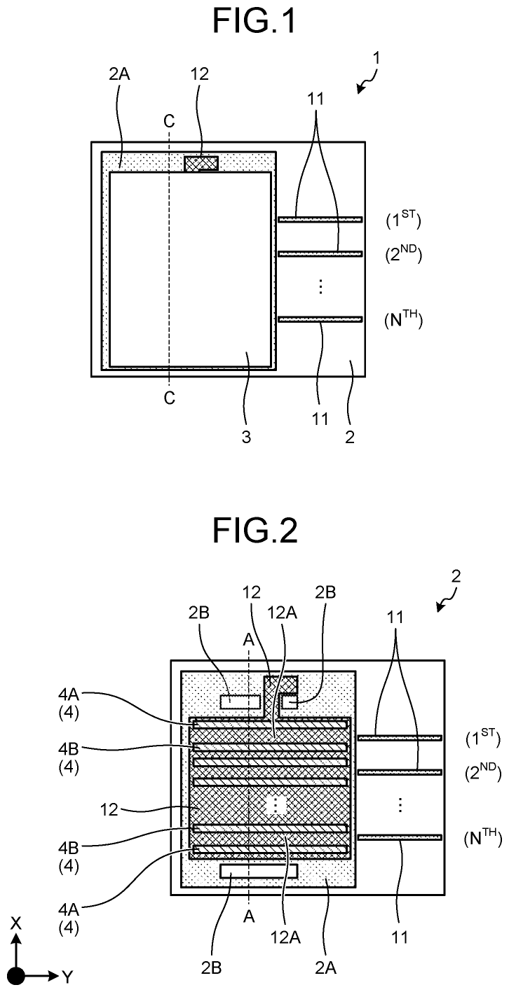

FIG. 1 is a schematic plan view illustrating an example of an optical device 1 according to a first embodiment. The optical device 1 illustrated in FIG. 1 includes a substrate 2 that includes N optical waveguides 11 and a chip 3 that includes N active layers 21, and allows the N optical waveguides 11 to be optically coupled to the N active layers 21 as a result of surface mounting the chip 3 on the substrate 2. Furthermore, N is equal to or greater than one. The substrate 2 is, for example, a silicon substrate. The chip 3 has a built-in compound semiconductor element, such as semiconductor laser or a semiconductor optical amplifier, that is constituted of an InP-based semiconductor. The active layers 21 are stripe shaped optical waveguides included in a compound semiconductor element. The N optical waveguides 11 and the N active layers 21 are formed at the same pitch.

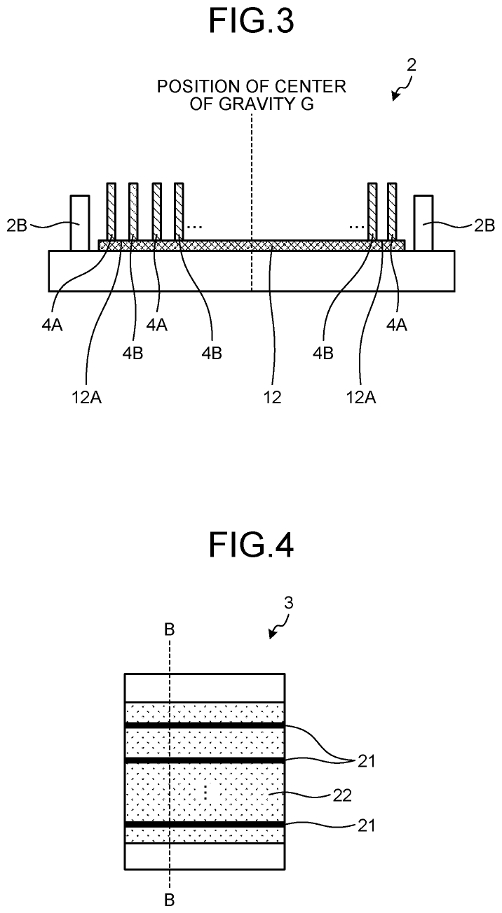

FIG. 2 is a schematic plan view illustrating an example of the substrate 2. FIG. 3 is a schematic cross-sectional diagram of the substrate 2 taken along line A-A illustrated in FIG. 2. The substrate 2 illustrated in FIG. 2 includes a mounting groove 2A that is used to mount therein the chip 3, and a plurality of bases 2B on which the chip 3 mounted on the mounting groove 2A is placed. The bases 2B are used to align the height of the optical axis of the active layers 21 included in the chip 3 and the optical waveguides 11 at the time when the chip 3 is placed such that the active layers 21 are optically coupled to the optical waveguides 11. The optical waveguides 11 included in the substrate 2 are silicon waveguides formed of upper and lower SiO₂ clad layers disposed on the substrate 2. The substrate 2 includes a substrate-side electrode 12 that is formed inside the mounting groove 2A. A plurality of solder bumps 4 are accordingly arranged on the bonding surface of the substrate-side electrode 12. A position of the center of gravity G illustrated in FIG. 3 is calculated on the basis of the coordinates of the center of gravity of all of the solder bumps 4 disposed on the substrate-side electrode 12 included in the substrate 2. The position of the center of gravity G is used to determine the positions of the solder bumps 4 that are arranged on the bonding surface of the substrate-side electrode 12.

On the substrate 2, if the X-axis and the Y-axis are defined, an area of a first bump 4A that is located at a position farther away from the position of the center of gravity G from among the solder bumps 4 that are located on both sides of a bonding surface 12A that is located opposite the N^{th} active layer 21 is defined as SAN, and the coordinates of the center of gravity of the first bump 4A are defined as (X_{AN}, Y_{AN}). Furthermore, an area of a second bump 4B that is located at a position closer to the position of the center of gravity G from among the solder bumps 4 that are located on both sides of the bonding surface 12A that is located opposite the Nth active layer 21 is defined as S_{BN}, and the coordinates of the center of gravity of the second bump 4B are defined as (X_{BN}, Y_{BN}). Then, the coordinates (X_{G}, Y_{G}) of the position of the center of gravity G of all of the solder bumps 4 are represented by Equation 1 below.

$${X}_{G} = \frac{{S}_{A 1} {X}_{A 1} + {S}_{B 1} {X}_{B 1} + … + {S}_{AN} {X}_{AN} + {S}_{BN} {X}_{BN}}{{S}_{A 1} + {S}_{B 1} + … + {S}_{AN} + {S}_{BN}} {Y}_{G} = \frac{{S}_{A 1} {Y}_{A 1} + {S}_{B 1} {Y}_{B 1} + … + {S}_{AN} {Y}_{AN} + {S}_{BN} {Y}_{BN}}{{S}_{A 1} + {S}_{B 1} + … + {S}_{AN} + {S}_{BN}} \qquad ( 1 )$$

At the first bump 4A located at the position farther away from the position of the center of gravity G, thermal stress produced caused by a difference between the thermal expansion coefficients of the chip 3 and the substrate 2 is large, and, in contrast, at the second bump 4B located at the position closer to the position of the center of gravity G, thermal stress is small. The effect of the thermal stress is suppressed by increasing the distance between the first bump 4A located at the position farther away from the position of the center of gravity G and the active layer 21, and a heat dissipation characteristic can be ensured by decreasing the distance between the second bump 4B located at the position closer to the position of the center of gravity G and the active layer 21. Here, the active layer 21 located on the chip 3 side is a light emitting layer constituted of a semiconductor quantum well structure (QW structure) or a semiconductor quantum dot structure (QD structure), is processed into a stripe shape used in a case of a semiconductor laser device or a semiconductor optical amplifier, and has a ridge structure or an embedded structure.

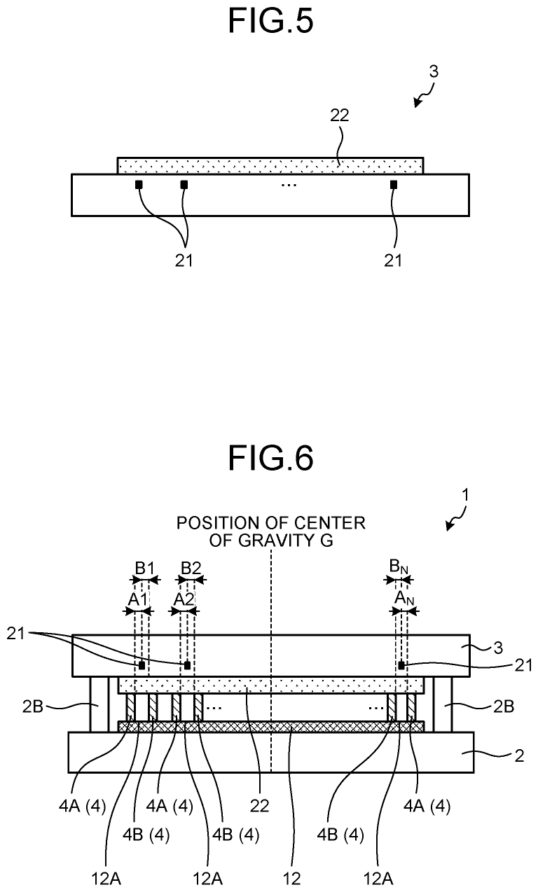

FIG. 4 is a schematic plan view illustrating an example of the chip 3. FIG. 5 is a schematic cross-sectional diagram of the chip 3 taken along line B-B illustrated in FIG. 4. The chip 3 illustrated in FIG. 4 includes a chip-side electrode 22 on the surface on which the substrate-side electrode 12 included in the substrate 2 is mounted. The chip-side electrode 22 is bonded to and mounted on the bonding surface of the substrate-side electrode 12 via the solder bump 4. When the chip 3 is mounted on the substrate 2, the active layer 21 included in the chip 3 is accordingly optically coupled to the optical waveguide 11.

FIG. 6 is a schematic cross-sectional diagram taken along line C-C illustrated in FIG. 1. The solder bumps 4 arranged on the bonding surface of the substrate-side electrode 12 illustrated in FIG. 6 are the first bump 4A and the second bump 4B that are disposed side by side with, for example, parallel to the active layer 21 on both sides of the bonding surface 12A that is located opposite the active layer 21 and that is included in the bonding surface of the substrate-side electrode 12 that is bonded to the chip-side electrode 22.

The first bump 4A is defined as the solder bump 4 that is located at the position farther away from the position of the center of gravity G of all of the solder bumps 4 that are disposed side by side with, for example, parallel to the active layer 21, and the second bump 4B is defined as the solder bump 4 that is located at the position closer to the position of the center of gravity G. The first bump 4A and the second bump 4B are accordingly arranged on the bonding surface of the substrate-side electrode 12 such that the distance between the first bump 4A and the bonding surface 12A is longer than the distance between the second bump 4B and the bonding surface 12A.

For example, in a case of the first active layer 21, the distance between the first bump 4A and the bonding surface 12A is denoted by A1, and the distance between the second bump 4B and the bonding surface 12A is denoted by B1. Then, the first bump 4A and the second bump 4B are arranged so as to be parallel to the first active layer 21 on the bonding surface of the substrate-side electrode 12 such that a requirement of the distance A1>the distance B1 is satisfied.

For example, in a case of the second active layer 21, the distance between the first bump 4A and the bonding surface 12A is denoted by A2, and the distance between the second bump 4B and the bonding surface 12A is denoted by B2. Then, the first bump 4A and the second bump 4B are arranged so as to be parallel to the second active layer 21 on the bonding surface of the substrate-side electrode 12 such that a requirement of the distance A2>the distance B2 is satisfied.

For example, in a case of the Nth active layer 21, the distance between the first bump 4A and the bonding surface 12A is denoted by AN, and the distance between the second bump 4B and the bonding surface 12A is denoted by BN. Then, the first bump 4A and the second bump 4B are arranged so as to be parallel to the Nth active layer 21 on the bonding surface of the substrate-side electrode 12 such that a requirement of the distance AN>the distance BN is satisfied.

In the optical device 1 according to the first embodiment, the first bump 4A and the second bump 4B are arranged on the substrate-side electrode 12 such that the distance AN between the first bump 4A and the bonding surface 12A is longer than the distance BN between the second bump 4B and the bonding surface 12A. Consequently, it is possible to ensure the heat dissipation characteristic by decreasing the distance BN between the second bump 4B located at the position closer to the position of the center of gravity G and the active layer 21 while suppressing the effect of the thermal stress by increasing the distance AN between the first bump 4A located at the position farther away from the position of the center of gravity G and the active layer 21. Then, it is possible to suppress a characteristic degradation of the compound semiconductor element included in the chip 3.

Furthermore, in the optical device 1 according to the first embodiment, a case has been described as an example in which all of the adjacent combinations of the first bump 4A and the second bump 4B are arranged on the substrate-side electrode 12 such that the distance AN between the first bump 4A and the bonding surface 12A is longer than the distance BN between the second bump 4B and the bonding surface 12A. However, the example is not limited to all of the combinations of the first bump 4A and the second bump 4B, and, at least one adjacent combination of the first bump 4A and the second bump 4B may be arranged such that the distance AN between the first bump 4A and the bonding surface 12A is longer than the distance BN between the second bump 4B and the bonding surface 12A, and appropriate modifications are possible.

Furthermore, in the optical device 1 according to the first embodiment, the structure in which the chip 3 including the N active layers 21 is mounted on the substrate 2 has been described as an example; however, the example is not limited to this. For example, an embodiment of an optical device 1A in which the chip 3 including the two active layers 21 is mounted on the substrate 2 may be used, and the embodiment thereof will be described as a second embodiment. In addition, by assigning the same reference numerals to components having the same configuration as those in the optical device 1 according to the first embodiment, overlapped descriptions of the configuration and the operation thereof will be omitted.

### (b) Second Embodiment

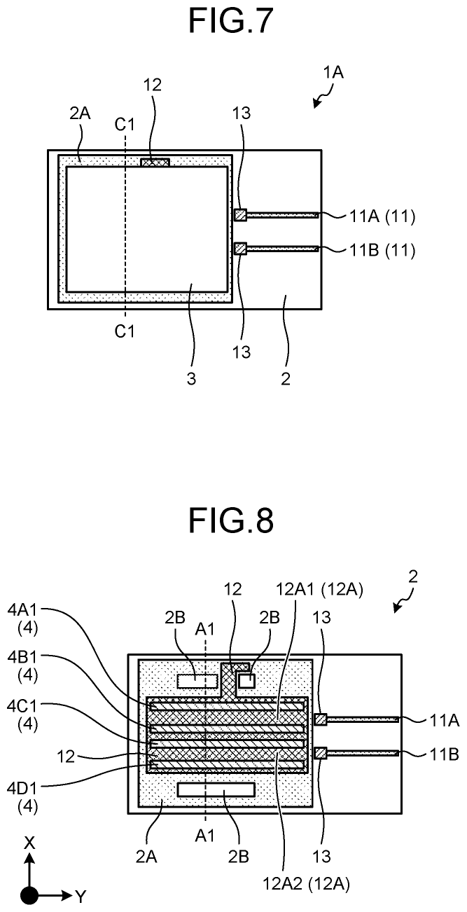

FIG. 7 is a schematic plan view illustrating an example of the optical device 1A according to the second embodiment. The optical device 1A illustrated in FIG. 7 includes the substrate 2 that has two built-in optical waveguides 11, and the chip 3 that has two built-in active layers 21. The two optical waveguides 11 include a first optical waveguide 11A and a second optical waveguide 11B. The two active layers 21 include a first active layer 21A that is optically coupled to the first optical waveguide 11A, and a second active layer 21B that is optically coupled to the second optical waveguide 11B.

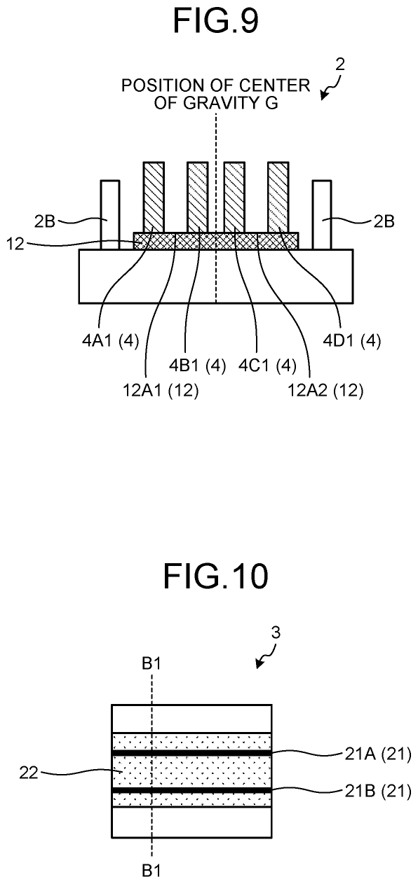

FIG. 8 is a schematic plan view illustrating an example of the substrate 2, and FIG. 9 is a schematic cross-sectional diagram of the substrate 2 taken along ling A1-A1 illustrated in FIG. 8. The substrate 2 illustrated in FIG. 8 includes the mounting groove 2A, the bases 2B, and spot size converters 13 that are arranged at an end of the respective optical waveguides 11. Each of the spot size converters 13 are converters that suppress a mode mismatch loss produced at the time of optical coupling with the respective active layers 21 included in the chip 3. In addition, the four solder bump 4 each having a stripe shape are arranged on the bonding surface of the substrate-side electrode 12. The solder bump 4 includes a first bump 4A1, a second bump 4B1, a third bump 4C1, and a fourth bump 4D1. The first bump 4A1 and the second bump 4B1 are arranged on both sides of a first bonding surface 12A1 that is located opposite the first active layer 21A and that is included in the bonding surface 12A of the substrate-side electrode 12 bonded to the chip-side electrode 22. The third bump 4C1 and the fourth bump 4D1 are arranged on both sides of a second bonding surface 12A2 that is located opposite the second active layer 21B and that is included in the bonding surface 12A of the substrate-side electrode 12 bonded to the chip-side electrode 22. The position of the center of gravity G illustrated in FIG. 9 is calculated by using the coordinates of the center of gravity of all of the solder bumps 4 arranged on the substrate-side electrode 12 included in the substrate 2. The position of the center of gravity G is accordingly used to determine the positions of the solder bumps 4 to be arranged on the bonding surface of the substrate-side electrode 12.

On the substrate 2, if the X-axis and the Y-axis are defined, an area of the first bump 4A1 that is located at a position farther away from the position of the center of gravity G between the solder bumps 4 that are located on both sides of a first bonding surface 12A1 that is located opposite the first active layer 21A is defined as S_{A1}, and the coordinates of the center of gravity of the first bump 4A1 are defined as (X_{A1}, Y_{A1}). Furthermore, an area of the second bump 4B1 that is located at a position closer to the position of the center of gravity G between the solder bumps 4 that are located on both sides of the first bonding surface 12A1 that is located opposite the first active layer 21A is defined as S_{B1}, and the coordinates of the center of gravity of the second bump 4B1 are defined as (X_{B2}, Y_{B2}). An area of the fourth bump 4D1 that is located at a position farther away from the position of the center of gravity G between the solder bumps 4 that are located on both sides of a second bonding surface 12A2 that is located opposite the second active layer 21B is defined as S_{A2}, and the coordinates of the center of gravity of the fourth bump 4D1 are (X_{A2}, Y_{A2}). Furthermore, an area of the third bump 4C1 that is located at a position closer to the position of the center of gravity G between the solder bumps 4 that are located on both sides of the second bonding surface 12A2 that is located opposite the second active layer 21B is defined as S_{B2}, and the coordinates of the center of gravity of the third bump 4C1 are defined as (X_{B2}, Y_{B2}). Then, on the basis of the coordinates of the center of gravity and the area of each of the solder bumps 4, the coordinates (X_{G}, Y_{G}) of the position of the center of gravity G of all of the solder bumps 4 are represented by Equation 2 below.

$${X}_{G} = \frac{{S}_{A 1} {X}_{A 1} + {S}_{B 1} {X}_{B 1} + {S}_{A 2} {X}_{A 2} + {S}_{B 2} {X}_{B 2}}{{S}_{A 1} + {S}_{B 1} + {S}_{A 2} + {S}_{B 2}} {Y}_{G} = \frac{{S}_{A 1} {Y}_{A 1} + {S}_{B 1} {Y}_{B 1} + {S}_{A 2} {Y}_{A 2} + {S}_{B 2} {Y}_{B 2}}{{S}_{A 1} + {S}_{B 1} + {S}_{A 2} + {S}_{B 2}} \qquad ( 2 )$$

At the first bump 4A1 located at the position farther away from the position of the center of gravity G, thermal stress produced caused by a difference between the thermal expansion coefficients of the chip 3 and the substrate 2 is large, and, in contrast, at the second bump 4B1 located at the position closer to the position of the center of gravity G, thermal stress is small. The effect of the thermal stress is suppressed by increasing the distance between the first bump 4A1 located at the position farther away from the position of the center of gravity G and the first active layer 21A, and a heat dissipation characteristic can be ensured by decreasing the distance between the second bump 4B1 located at the position closer to the position of the center of gravity G and the first active layer 21A. At the fourth bump 4D1 located at the position farther away from the position of the center of gravity G, thermal stress produced caused by a difference between the thermal expansion coefficients of the chip 3 and the substrate 2 is large, and, in contrast, at the third bump 4C1 located at the position closer to the position of the center of gravity G, thermal stress is small. The effect of the thermal stress is suppressed by increasing the distance between the fourth bump 4D1 located at the position farther away from the position of the center of gravity G and the second active layer 21B, and a heat dissipation characteristic can be ensured by decreasing the distance between the third bump 4C1 located at the position closer to the position of the center of gravity G and the second active layer 21B.

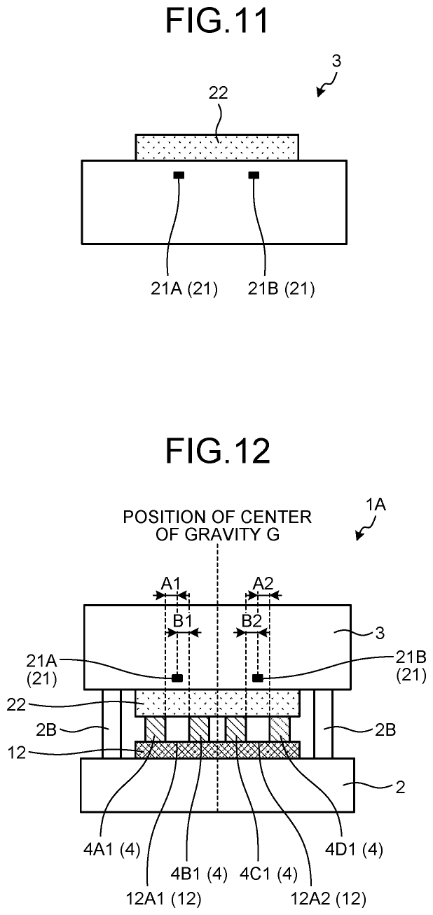

FIG. 10 is a schematic plan view illustrating an example of the chip 3, and FIG. 11 is a schematic cross-sectional diagram of the chip 3 taken along line B1-B1 illustrated in FIG. 10. The chip-side electrode 22 included in the chip 3 illustrated in FIG. 10 is bonded to and mounted on the bonding surface of the substrate-side electrode 12 via the solder bump 4. When the chip 3 is mounted on the substrate 2, the first active layer 21A included in the chip 3 is accordingly optically coupled to the first optical waveguide 11A, and the second active layer 21B is accordingly optically coupled to the second optical waveguide 11B.

FIG. 12 is a schematic cross-sectional diagram taken along line C1-C1 illustrated in FIG. 7. The first bump 4A1 arranged on the bonding surface of the substrate-side electrode 12 illustrated in FIG. 12 is defined as the solder bump 4 that is located at the position farther away from the position of the center of gravity G of all of the solder bumps 4, and the second bump 4B1 arranged on the bonding surface of the substrate-side electrode 12 is defined as the solder bump 4 that is located at the position closer to the position of the center of gravity G. The first bump 4A1 and the second bump 4B1 are arranged on the substrate-side electrode 12 such that the distance between the first bump 4A1 and the first bonding surface 12A1 is longer than the distance between the second bump 4B1 and the first bonding surface 12A1.

For example, in a case of the first active layer 21A, the distance between the first bump 4A1 and the first bonding surface 12A1 is denoted by the distance A1, and the distance between the second bump 4B1 and the first bonding surface 12A1 is denoted by the distance B1. Then, the first bump 4A1 and the second bump 4B1 are arranged on the bonding surface of the substrate-side electrode 12 so as to be parallel to the first active layer 21A such that a requirement of the distance A1>the distance B1 is satisfied.

The fourth bump 4D1 arranged on the bonding surface of the substrate-side electrode 12 is defined as the solder bump 4 that is located at the position farther away from the position of the center of gravity G, and the third bump 4C1 arranged on the bonding surface of the substrate-side electrode 12 is defined as the solder bump 4 that is located at the position closer to the position of the center of gravity G. The third bump 4C1 and the fourth bump 4D1 are arranged on the substrate-side electrode 12 such that the distance between the third bump 4C1 and the second bonding surface 12A2 is longer than the distance between the fourth bump 4D1 and the second bonding surface 12A2.

For example, in a case of the second active layer 21B, the distance between the fourth bump 4D1 and the second bonding surface 12A2 is denoted by the distance A2, and the distance between the third bump 4C1 and the second bonding surface 12A2 is denoted by the distance B2. Then, the third bump 4C1 and the fourth bump 4D1 are arranged so as to be parallel to the second active layer 21B on the bonding surface of the substrate-side electrode 12 such that a requirement of the distance A2>the distance B2 is satisfied.

In addition, it is assumed that the substrate 2 is made of silicon, the solder bump 4 is made of AuSn, the substrate-side electrode 12 is formed of an Au electrode, the chip-side electrode 22 is formed of an Au electrode, and the optical waveguide 11 is formed of a silicon waveguide constituted of upper and lower clad layers made of SiO₂. For example, the first bump 4A1, the second bump 4B1, the third bump 4C1, and the fourth bump 4D1 are arranged on the substrate-side electrode 12 under the condition of the distance A1=the distance A2=75 μm, and the distance B1=the distance B2=25 μm. Accordingly, regarding the structure according to the present embodiment, when a thermal stress analysis (thermal analysis: setting the rear surface of the silicon substrate to 45° C., and a temperature distribution at the time of a gross heating value of 500 mW in the active layer 21; stress analysis: AuSn junction formation at 300° C., and a stress distribution at the time of a room air temperature of 30° C.) has been conducted, the maximum temperature of the active layer 21 is 59° C., and the maximum stress applied to the active layer 21 is 66 MPa. In contrast, the same thermal stress analysis has been conducted on the structure (comparative example) in which the solder bumps 4 that are disposed at a symmetrical interval on both sides of the bonding surface 12A that is located opposite the active layer 21 are constituted under the condition of the distance A1=the distance A2=the distance B1=the distance B2=25 μm. In a case of the comparative example the maximum temperature of the active layer 21 is 59° C., and the maximum stress applied to the active layer 21 is 101 MPa. In other words, in the optical device 1A according to the present embodiment, it has been confirmed that it is possible to cope with both of suppression of the thermal stress and securement of the heat dissipation characteristic.

In the optical device 1A according to the second embodiment, the first bump 4A1 and the second bump 4B1 are arranged on the substrate-side electrode 12 such that the distance A1 between the first bump 4A1 and the first bonding surface 12A1 is longer than the distance B1 between the second bump 4B1 and the first bonding surface 12A1. Consequently, it is possible to ensure the heat dissipation characteristic by decreasing the distance B1 between the second bump 4B1 and the first active layer 21A while suppressing the effect of the thermal stress by increasing the distance A1 between the first bump 4A1 and the first active layer 21A. In addition, it is possible to suppress a characteristic degradation of the compound semiconductor element included in the chip 3.

In the optical device 1A, the third bump 4C1 and the fourth bump 4D1 are arranged on the substrate-side electrode 12 such that the distance A2 between the fourth bump 4D1 and the second bonding surface 12A2 is longer than the distance B2 between the third bump 4C1 and the second bonding surface 12A2. Consequently, it is possible to ensure the heat dissipation characteristic by decreasing the distance B2 between the third bump 4C1 and the second active layer 21B while suppressing the effect of the thermal stress by increasing the distance A2 between the fourth bump 4D1 and the second active layer 21B. In addition, it is possible to suppress a characteristic degradation of the compound semiconductor element included in the chip 3.

In addition, in the optical device 1A according to the second embodiment, a case has been described as an example in which the first active layer 21A is disposed so as to be parallel to the first bump 4A1 and the second bump 4B1, and the second active layer 21B is disposed so as to be parallel to the third bump 4C1 and the fourth bump 4D1. However, the example is not limited to this. For example, both of the second bump 4B1 and the third bump 4C1 may be used as the single bump 4, and the embodiment thereof will be described below as a the third embodiment. In addition, by assigning the same reference numerals to components having the same configuration as those in the optical device 1A according to the second embodiment, overlapped descriptions of the configuration and the operation thereof will be omitted.

### (c) Third Embodiment

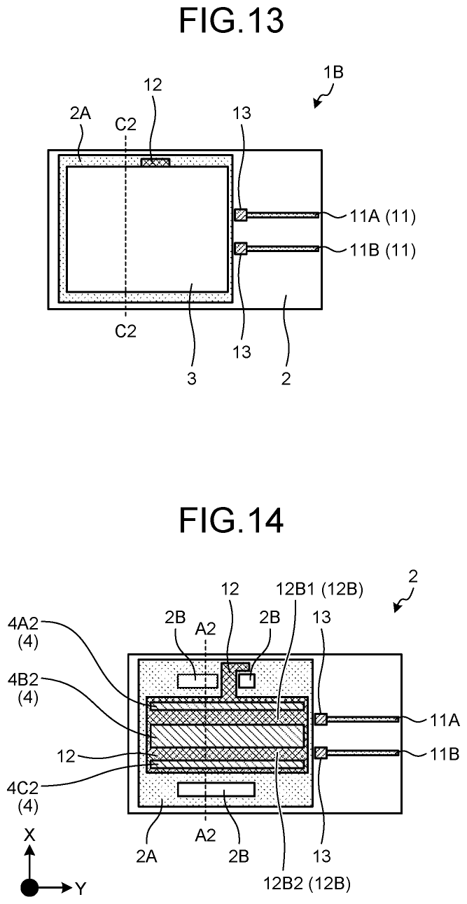

FIG. 13 is a schematic plan view illustrating an example of an optical device 1B according to the third embodiment. The optical device 1B illustrated in FIG. 13 includes the substrate 2 that has the two built-in optical waveguides 11, and the chip 3 that has the built-in active layer 21 that is optically coupled to each of the optical waveguides 11. The two optical waveguides 11 include the first optical waveguide 11A and the second optical waveguide 11B. The active layer 21 includes the first active layer 21A that is optically coupled to the first optical waveguide 11A and the second active layer 21B that is optically coupled to the second optical waveguide 11B.

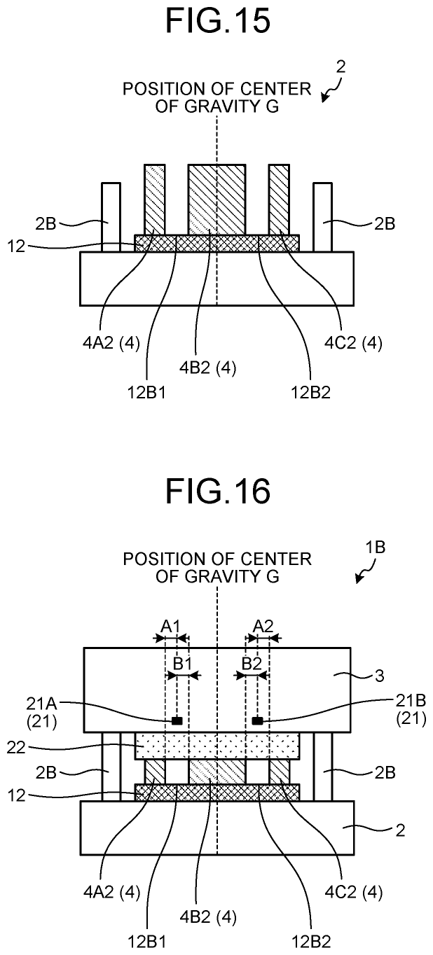

FIG. 14 is a schematic plan view illustrating an example of the substrate 2, and FIG. 15 is a schematic cross-sectional diagram of the substrate 2 taken along line A2-A2 illustrated in FIG. 14. The three solder bumps 4 are arranged on the bonding surface of the substrate-side electrode 12 illustrated in FIG. 15. The solder bump 4 includes a first bump 4A2, a second bump 4B2, and a third bump 4C2. In addition, the width of the second bump 4B2 is greater than the width of the first bump 4A2 because the second bump 4B2 functions as both of the second bump 4B1 and the third bump 4C1 according to the second embodiment. The first bump 4A2 and the second bump 4B2 are arranged on both sides of a first bonding surface 12B1 that is located opposite the first active layer 21A and that is included in a bonding surface 12B of the substrate-side electrode 12 bonded to the chip-side electrode 22. The second bump 4B2 and the third bump 4C2 are arranged on both sides of a second bonding surface 12B2 that is located opposite the second active layer 21B and that is included in the bonding surface 12B of the substrate-side electrode 12 bonded to the chip-side electrode 22. The position of the center of gravity G illustrated in FIG. 15 is calculated by using the coordinates of the center of gravity of all of the solder bumps 4 arranged on the substrate-side electrode 12 included in the substrate 2. The position of the center of gravity G is accordingly used to determine the positions of the solder bumps 4 to be arranged on the bonding surface of the substrate-side electrode 12.

On the substrate 2, if the X-axis and the Y-axis are defined, an area of the first bump 4A2 that is located at a position farther away from the position of the center of gravity G between the solder bumps 4 that are located on both sides of the first bonding surface 12B1 that is located opposite the first active layer 21A is defined as S_{A1}, and the coordinates of the center of gravity of the first bump 4A2 are defined as (X_{A1}, Y_{A1}). Furthermore, an area of the second bump 4B2 that is located at a position closer to the position of the center of gravity G between the solder bumps 4 that are located on both sides of the first bonding surface 12B1 that is located opposite the first active layer 21A is defined as S_{B1}, and the coordinates of the center of gravity of the second bump 4B2 are defined as (X_{B1}, Y_{B1}). An area of the third bump 4C2 that is located at a position farther away from the position of the center of gravity G between the solder bumps 4 that are located on both sides of the second bonding surface 12B2 that is located opposite the second active layer 21B is defined as S_{A2}, and the coordinates of the center of gravity of the third bump 4C2 are defined as (X_{A2}, Y_{A2}). Then, on the basis of the coordinates of the center of gravity and the area of each of the solder bumps 4, the coordinates (X_{G}, Y_{G}) of the position of the center of gravity G of all of the solder bumps 4 are calculated.

At the first bump 4A2 located at the position farther away from the position of the center of gravity G, thermal stress produced caused by a difference between the thermal expansion coefficients of the chip 3 and the substrate 2 is large, and, in contrast, at the second bump 4B2 located at the position closer to the position of the center of gravity G, the thermal stress is small. The effect of the thermal stress is suppressed by increasing the distance between the first bump 4A2 located at the position farther away from the position of the center of gravity G and the first active layer 21A, and a heat dissipation characteristic can be ensured by decreasing the distance between the second bump 4B2 located at the position closer to the position of the center of gravity G and the first active layer 21A. At the third bump 4C2 located at the position farther away from the position of the center of gravity G, thermal stress produced caused by a difference between the thermal expansion coefficients of the chip 3 and the substrate 2 is large, and, in contrast, at the second bump 4B2 located at the position closer to the position of the center of gravity G, thermal stress is small. The effect of the thermal stress is suppressed by increasing the distance between the third bump 4C2 located at the position farther away from the position of the center of gravity G and the second active layer 21B, and a heat dissipation characteristic can be ensured by decreasing the distance between the second bump 4B2 located at the position closer to the position of the center of gravity G and the second active layer 21B.

FIG. 16 is a schematic cross-sectional diagram taken along line C2-C2 illustrated in FIG. 13. The first bump 4A2 arranged on the bonding surface of the substrate-side electrode 12 illustrated in FIG. 16 is defined as the solder bump 4 that is located at the position farther away from the position of the center of gravity G of all of the solder bumps 4, and the second bump 4B2 arranged on the bonding surface of the substrate-side electrode 12 is defined as the solder bump 4 that is located at the position closer to the position of the center of gravity G. The first bump 4A2 and the second bump 4B2 that are disposed parallel to the first active layer 21A are arranged on the bonding surface of the substrate-side electrode 12 such that the distance between the first bump 4A2 and the first bonding surface 12B1 is longer than the distance between the second bump 4B2 and the first bonding surface 12B1.

For example, in a case of the first active layer 21A, the distance between the first bump 4A2 and the first bonding surface 12B1 is denoted by the distance A1, and the distance between the second bump 4B2 and the first bonding surface 12B1 is denoted by the distance B1. Then, the first bump 4A2 and the second bump 4B2 are arranged on the bonding surface of the substrate-side electrode 12 so as to be parallel to the first active layer 21A such that the requirement of the distance A1>the distance B1 is satisfied.

The third bump 4C2 arranged on the bonding surface of the substrate-side electrode 12 is defined as the solder bump 4 that is located at the position farther away from the position of the center of gravity G, and the second bump 4B2 arranged on the bonding surface of the substrate-side electrode 12 is defined as the solder bump 4 that is located at the position closer to the position of the center of gravity G. The second bump 4B2 and the third bump 4C2 that are disposed parallel to the second active layer 21B are arranged on the bonding surface of the substrate-side electrode 12 such that the distance between the second bump 4B2 and the second bonding surface 12B2 is longer than the distance between the third bump 4C2 and the second bonding surface 12B2.

For example, in a case of the second active layer 21B, the distance between the third bump 4C2 and the second bonding surface 12B2 is denoted by the distance A2, and the distance between the second bump 4B2 and the second bonding surface 12B2 is denoted by the distance B2. Then, the second bump 4B2 and the third bump 4C2 are accordingly arranged on the bonding surface of the substrate-side electrode 12 so as to be parallel to the second active layer 21B such that the requirement of the distance A2>the distance B2 is satisfied.

In the optical device 1B according to the third embodiment, the first bump 4A2 and the second bump 4B2 are arranged on the substrate-side electrode 12 such that the distance A1 between the first bump 4A2 and the first bonding surface 12B1 is longer than the distance B1 between the second bump 4B2 and the first bonding surface 12B1. Consequently, it is possible to ensure the heat dissipation characteristic by decreasing the distance B1 between the second bump 4B2 and the first active layer 21A while suppressing the effect of the thermal stress by increasing the distance A1 between the first bump 4A2 and the first active layer 21A. In addition, it is possible to suppress the heat dissipation characteristic by increasing the area of the second bump 4B2.

In the optical device 1B, the second bump 4B2 and the third bump 4C2 are arranged on the substrate-side electrode 12 such that the distance A2 between the third bump 4C2 and the second bonding surface 12B2 is longer than the distance B2 between the second bump 4B2 and the second bonding surface 12B2. Consequently, it is possible to ensure the heat dissipation characteristic by decreasing the distance B2 between the second bump 4B2 and the second active layer 21B while suppressing the effect of the thermal stress by increasing the distance A2 between the third bump 4C2 and the second active layer 21B.

In addition, a case has been described as an example in which the first bump 4A1 and the second bump 4B1 that are disposed parallel to the first active layer 21A and the third bump 4C1 and the fourth bump 4D1 that are disposed parallel to the second active layer 21B are arranged on the bonding surface 12A of the substrate-side electrode 12 included in the optical device 1A according to the second embodiment. However, the solder bump 4 arranged on the bonding surface 12A of the substrate-side electrode 12 is not limited to this, and appropriate modifications are possible. Accordingly, an embodiment thereof will be described as a fourth embodiment.

### (d) Fourth Embodiment

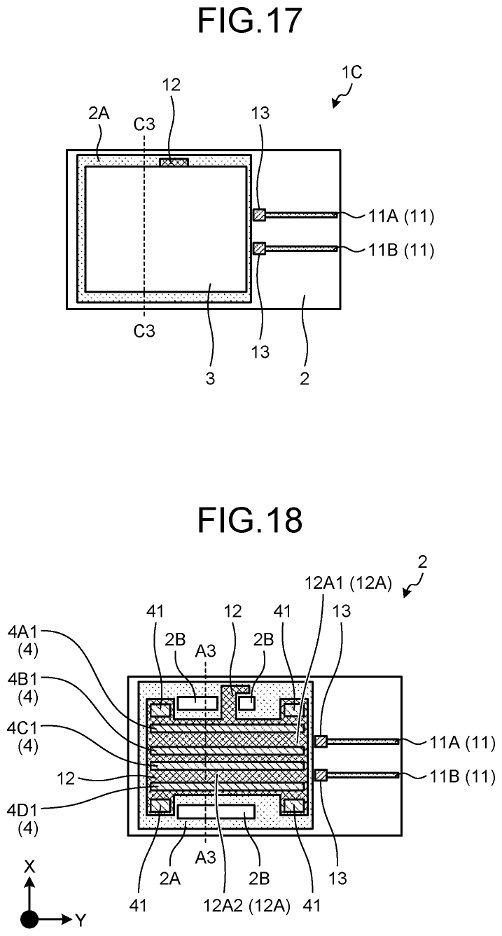

FIG. 17 is a schematic plan view illustrating an example of an optical device 1C according to the fourth embodiment. The optical device 1C illustrated in FIG. 17 includes the substrate 2 that has two built-in optical waveguides 11, and the chip 3 that has the built-in active layer 21 that is optically coupled to each of the optical waveguides 11. The two optical waveguides 11 include the first optical waveguide 11A and the second optical waveguide 11B. The active layer 21 includes the first active layer 21A that is optically coupled to the first optical waveguide 11A, and the second active layer 21B that is optically coupled to the second optical waveguide 11B.

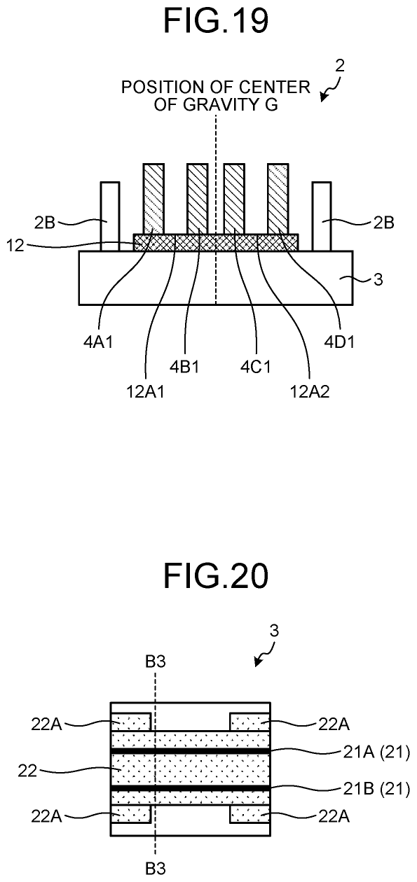

FIG. 18 is a schematic plan view illustrating an example of the substrate 2, and FIG. 19 is a schematic cross-sectional diagram of the substrate 2 taken along line A3-A3 illustrated in FIG. 18. In addition to the four solder bumps 4, other square solder bumps 41 are arranged on the bonding surface of the substrate-side electrode 12 included in the substrate 2 illustrated in FIG. 18. The four solder bumps 4 include the first bump 4A1, the second bump 4B1, the third bump 4C1, and the fourth bump 4D1. The first bump 4A1 and the second bump 4B1 are arranged on both sides of the first bonding surface 12A1 that is located opposite the first active layer 21A and that is included in the bonding surface 12A of the substrate-side electrode 12 bonded to the chip-side electrode 22. The third bump 4C1 and the fourth bump 4D1 are arranged on both sides of the second bonding surface 12A2 that is located opposite the second active layer 21B and that is included in the bonding surface 12A of the substrate-side electrode 12 bonded to the chip-side electrode 22. The other square solder bumps 41 have a function to strengthen the bonding between the substrate-side electrode 12 and the chip-side electrode 22.

The position of the center of gravity G illustrated in FIG. 19 is calculated by using the coordinates of the center of gravity of all of the solder bumps 4 arranged on the substrate-side electrode 12 included in the substrate 2. The position of the center of gravity G is accordingly used to determine the positions of the solder bumps 4 to be arranged on the bonding surface of the substrate-side electrode 12.

On the substrate 2, if the X-axis and the Y-axis are defined, an area of the first bump 4A1 that is located at a position farther away from the position of the center of gravity G between the solder bumps 4 that are located on both sides of the first bonding surface 12A1 that is located opposite the first active layer 21A is defined as S_{A1}, and the coordinates of the center of gravity of the first bump 4A1 are defined as (X_{A1}, Y_{A1}). Furthermore, an area of the second bump 4B1 that is located at a position closer to the position of the center of gravity G between the solder bumps 4 that are located on both sides of the first bonding surface 12A1 that is located opposite the first active layer 21A is defined as S_{B1}, and the coordinates of the center of gravity of the second bump 4B1 are defined as (X_{B1}, Y_{B1}). An area of the fourth bump 4D1 that is located at a position farther away from the position of the center of gravity G between the solder bumps 4 that are located on both sides of the second bonding surface 12A2 that is located opposite the second active layer 21B is defined as S_{A2}, and the coordinates of the center of gravity of the fourth bump 4D1 are defined as (X_{A2}, Y_{A2}). Furthermore, an area of the third bump 4C1 that is located at a position closer to the position of the center of gravity G between the solder bumps 4 that are located on both sides of the second bonding surface 12A2 that is located opposite the second active layer 21B is defined as S_{B2}, and the coordinates of the center of gravity of the third bump 4C1 are defined as (X_{B2}, Y_{B2}). In addition, in consideration of the area of the solder bumps 41 located at the four corners and the coordinates of the center of gravity, the coordinates (X_{G}, Y_{G}) of the position of the center of gravity G of all of the solder bumps 4 are calculated on the basis of the coordinates of the center of gravity and the area of each of the first bump 4A1, the second bump 4B1, the third bump 4C1, and the fourth bump 4D1.

At the first bump 4A1 located at the position farther away from the position of the center of gravity G, thermal stress produced caused by a difference between the thermal expansion coefficients of the chip 3 and the substrate 2 is large, and, in contrast, at the second bump 4B1 located at the position closer to the position of the center of gravity G, thermal stress is small. The effect of the thermal stress is suppressed by increasing the distance between the first bump 4A1 located at the position farther away from the position of the center of gravity G and the first active layer 21A, and a heat dissipation characteristic can be ensured by decreasing the distance between the second bump 4B1 located at the position closer to the position of the center of gravity G and the first active layer 21A. At the fourth bump 4D1 located at the position farther away from the position of the center of gravity G, thermal stress produced caused by a difference between the thermal expansion coefficients of the chip 3 and the substrate 2 is large, and, in contrast, at the third bump 4C1 located at the position closer to the position of the center of gravity G, thermal stress is small. The effect of the thermal stress is suppressed by increasing the distance between the fourth bump 4D1 located at the position farther away from the position of the center of gravity G and the second active layer 21B, and a heat dissipation characteristic can be ensured by decreasing the distance between the third bump 4C1 located at the position closer to the position of the center of gravity G and the second active layer 21B.

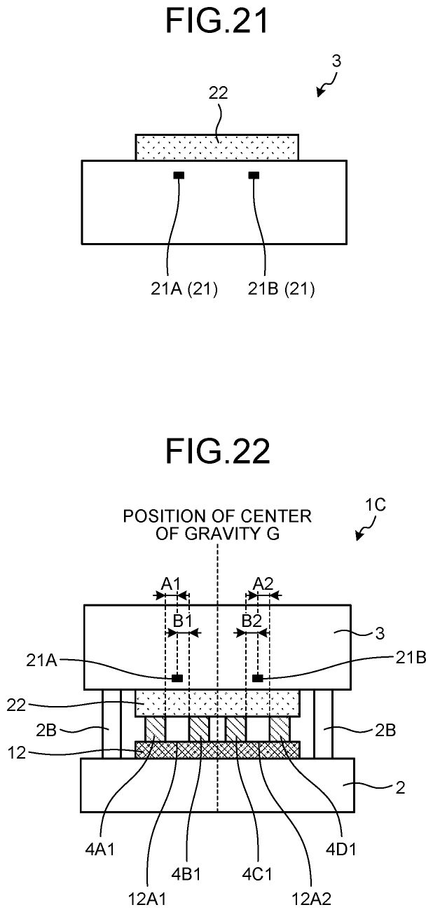

FIG. 20 is a schematic plan view illustrating an example of the chip 3, and FIG. 21 is a schematic cross-sectional diagram of the chip 3 taken along line B3-B3 illustrated in FIG. 20. A surface 22A of the chip-side electrode 22 included in the chip 3 illustrated in FIG. 20 is bonded on the bonding surface 12A of the substrate-side electrode 12 via the four solder bumps 4 and the other square solder bumps 41. When the chip 3 is mounted on the substrate 2, the first active layer 21A included in the chip 3 is accordingly optically coupled to the first optical waveguide 11A that is disposed on the substrate 2, and the second active layer 21B is accordingly optically coupled to the second optical waveguide 11B that is disposed on the substrate 2.

FIG. 22 is a schematic cross-sectional diagram taken along line C3-C3 illustrated in FIG. 17. The first bump 4A1 arranged on the bonding surface of the substrate-side electrode 12 illustrated in FIG. 22 is defined as the solder bump 4 that is located at the position farther away from the position of the center of gravity G of all of the solder bumps 4, and the second bump 4B1 arranged on the bonding surface of the substrate-side electrode 12 is defined as the solder bump 4 that is located at the position closer to the position of the center of gravity G. The first bump 4A1 and the second bump 4B1 that are disposed parallel to the first active layer 21A are arranged on the substrate-side electrode 12 such that the distance between the first bump 4A1 and the first bonding surface 12A1 is longer than the distance between the second bump 4B1 and the first bonding surface 12A1.

For example, in a case of the first active layer 21A, the distance between the first bump 4A1 and the first bonding surface 12A1 is denoted by the distance A1, and the distance between the second bump 4B1 and the first bonding surface 12A1 is denoted by the distance B1. Then, the first bump 4A1 and the second bump 4B1 are arranged on the bonding surface of the substrate-side electrode 12 so as to be parallel to the first active layer 21A such that the requirement of the distance A1>the distance B1 is satisfied.

The fourth bump 4D1 arranged on the bonding surface of the substrate-side electrode 12 is defined as the solder bump 4 that is located at the position farther away from the position of the center of gravity G, and the third bump 4C1 arranged on the bonding surface of the substrate-side electrode 12 is defined as the solder bump 4 that is located at the position closer to the position of the center of gravity G. The third bump 4C1 and the fourth bump 4D1 that are disposed parallel to the second active layer 21B are arranged on the substrate-side electrode 12 such that the distance between the third bump 4C1 and the second bonding surface 12A2 is longer than the distance between the fourth bump 4D1 and the second bonding surface 12A2.

For example, in a case of the second active layer 21B, the distance between the fourth bump 4D1 and the second bonding surface 12A2 is denoted by the distance A2, and the distance between the third bump 4C1 and the second bonding surface 12A2 is denoted by the distance B2. Then, the third bump 4C1 and the fourth bump 4D1 are accordingly arranged on the bonding surface of the substrate-side electrode 12 so as to be parallel to the second active layer 21B such that the requirement of the distance A2>the distance B2 is satisfied.

In the optical device 1C according to the fourth embodiment, the first bump 4A1 and the second bump 4B1 are arranged on the substrate-side electrode 12 such that the distance A1 between the first bump 4A1 and the first bonding surface 12A1 is longer than the distance B1 between the second bump 4B1 and the first bonding surface 12A1. Consequently, it is possible to ensure the heat dissipation characteristic by decreasing the distance B1 between the second bump 4B1 and the first active layer 21A while suppressing the effect of the thermal stress by increasing the distance A1 between the first bump 4A1 and the first active layer 21A.

In the optical device 1C, the third bump 4C1 and the fourth bump 4D1 are arranged on the substrate-side electrode 12 such that the distance A2 between the fourth bump 4D1 and the second bonding surface 12A2 is longer than the distance B2 between the third bump 4C1 and the second bonding surface 12A2. Consequently, it is possible to ensure the heat dissipation characteristic by decreasing the distance B2 between the third bump 4C1 and the second active layer 21B while suppressing the effect of the thermal stress by increasing the distance A2 between the fourth bump 4D1 and the second active layer 21B.

In addition, a case has been described as an example in which the bonding surface of the substrate-side electrode 12 included in the optical device 1A according to the second embodiment is bonded by using the first bump 4A1, the second bump 4B1, the third bump 4C1, and the fourth bump 4D1 that are continuously and linearly arranged. However, the solder bump 4 may be constituted by using a plurality of split bumps 4X instead of using the single solder bump 4 that is continuously and linearly arranged, and an embodiment thereof will be described as a fifth embodiment.

### (e) Fifth Embodiment

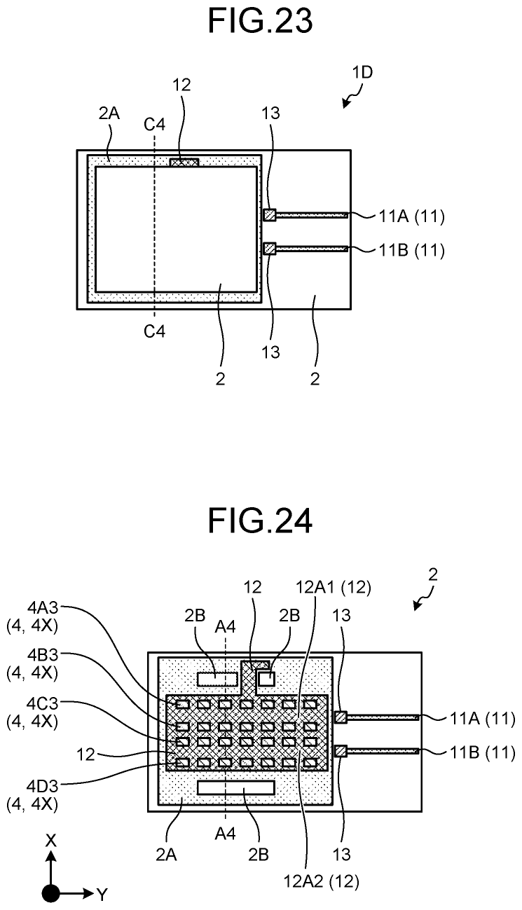

FIG. 23 is a schematic plan view illustrating an example of an optical device 1D according to the fifth embodiment. The optical device 1D illustrated in FIG. 23 includes the substrate 2 that has the two built-in optical waveguides 11, and the chip 3 that has the two built-in active layers 21.

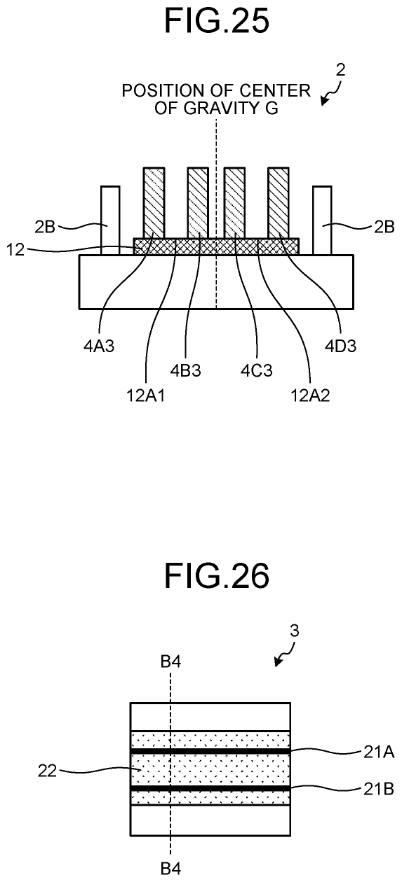

FIG. 24 is a schematic plan view illustrating an example of the substrate 2, and FIG. 25 is a schematic cross-sectional diagram of the substrate 2 taken along line A4-A4 illustrated in FIG. 24. The four solder bumps 4 are arranged on the bonding surface of the substrate-side electrode 12 included in the substrate 2 illustrated in FIG. 24. The solder bump 4 includes a first bump group 4A3, a second bump group 4B3, a third bump group 4C3, and a fourth bump group 4D3.

The first bump group 4A3 is formed by arranging the plurality of split bumps 4X in a linear manner instead of using continuous linear arrangement. The second bump group 4B3 is formed by arranging the plurality of split bumps 4X in a linear manner. The third bump group 4C3 is formed by arranging the plurality of split bumps 4X in a linear manner. The fourth bump group 4D3 is formed by arranging the plurality of split bumps 4X in a linear manner.

The first bump group 4A3 and the second bump group 4B3 are arranged on both sides of the first bonding surface 12A1 that is located opposite the first active layer 21A and that is included in the bonding surface 12A of the substrate-side electrode 12 bonded to the chip-side electrode 22. The third bump group 4C3 and the fourth bump group 4D3 are arranged on both sides of the second bonding surface 12A2 that is located opposite the second active layer 21B and that is included in the bonding surface 12A of the substrate-side electrode 12 bonded to the chip-side electrode 22.

The position of the center of gravity G illustrated in FIG. 25 is calculated by using the coordinates of the center of gravity of all of the solder bumps 4 arranged on the substrate-side electrode 12 included in the substrate 2. The position of the center of gravity G is accordingly used to determine the positions of the solder bumps 4 to be arranged on the bonding surface of the substrate-side electrode 12.

On the substrate 2, if the X-axis and the Y-axis are defined, an area of the first bump group 4A3 that is located at a position farther away from the position of the center of gravity G between the solder bumps 4 that are located on both sides of the first bonding surface 12A1 that is located opposite the first active layer 21A is defined as S_{A1}, and the coordinates of the center of gravity of the first bump group 4A3 are defined as (X_{A1}, Y_{A1}). Furthermore, an area of the second bump group 4B3 that is located at a position closer to the position of the center of gravity G between the solder bumps 4 that are located on both sides of the first bonding surface 12A1 that is located opposite the first active layer 21A is defined as S_{B1}, and the coordinates of the center of gravity of the second bump group 4B3 are defined as (X_{B1}, Y_{B1}). An area of the fourth bump group 4D3 that is located at a position farther away from the position of the center of gravity G between the solder bumps 4 that are located on both sides of the second bonding surface 12A2 that is located opposite the second active layer 21B is defined as S_{A2}, and the coordinates of the center of gravity of the fourth bump group 4D3 are defined as (X_{A2}, Y_{A2}). Furthermore, an area of the third bump group 4C3 that is located at a position closer to the position of the center of gravity G between the solder bumps 4 that are located on both sides of the second bonding surface 12A2 that is located opposite the second active layer 21B is defined as S_{B2}, and the coordinates of the center of gravity of the third bump group 4C3 are defined as (X_{B2}, Y_{B2}). Then, the coordinates (X_{G}, Y_{G}) of the position of the center of gravity G of all of the solder bumps 4 are calculated on the basis of the coordinates of the center of gravity and the area of the first bump group 4A3, the second bump group 4B3, the third bump group 4C3, and the fourth bump group 4D3.

At the first bump group 4A3 located at the position farther away from the position of the center of gravity G, thermal stress produced caused by a difference between the thermal expansion coefficients of the chip 3 and the substrate 2 is large, and, in contrast, at the second bump group 4B3 located at the position closer to the position of the center of gravity G, the thermal stress is small. The effect of the thermal stress is suppressed by increasing the distance between the first bump group 4A3 located at the position farther away from the position of the center of gravity G and the first active layer 21A, and a heat dissipation characteristic can be ensured by decreasing the distance between the second bump group 4B3 located at the position closer to the position of the center of gravity G and the first active layer 21A. At the fourth bump group 4D3 located at the position farther away from the position of the center of gravity G, thermal stress produced caused by a difference between the thermal expansion coefficients of the chip 3 and the substrate 2 is large, and, in contrast, at the third bump group 4C3 located at the position closer to the position of the center of gravity G, thermal stress is small. The effect of the thermal stress is suppressed by increasing the distance between the fourth bump group 4D3 located at the position farther away from the position of the center of gravity G and the second active layer 21B, and a heat dissipation characteristic can be ensured by decreasing the distance between the third bump group 4C3 located at the position closer to the position of the center of gravity G and the second active layer 21B.

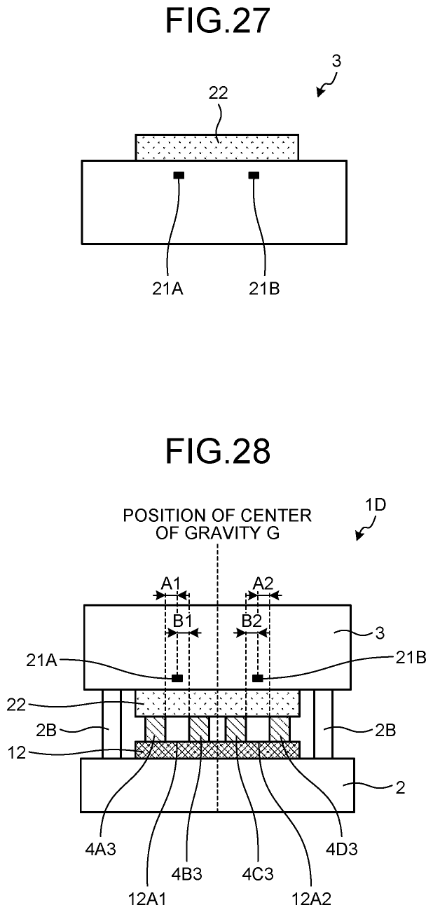

FIG. 26 is a schematic plan view illustrating an example of the chip 3, and FIG. 27 is a schematic cross-sectional diagram of the chip 3 taken along line B4-B4 illustrated in FIG. 26. The chip-side electrode 22 included in the chip 3 illustrated in FIG. 26 is bonded on the bonding surface of the substrate-side electrode 12 via the solder bump 4. When the chip 3 is mounted on the substrate 2, the first active layer 21A included in the chip 3 is accordingly optically coupled to the first optical waveguide 11A that is disposed on the substrate 2, and the second active layer 21B is accordingly optically coupled to the second optical waveguide 11B disposed on the substrate 2.

FIG. 28 is a schematic cross-sectional diagram taken along line C4-C4 illustrated in FIG. 23. The first bump group 4A3 arranged on the bonding surface of the substrate-side electrode 12 illustrated in FIG. 28 is defined as a bump group that is located at the position farther away from the position of the center of gravity G of all of the solder bumps 4, and the second bump group 4B3 arranged on the bonding surface of the substrate-side electrode 12 is defined as a bump group that is located at the position closer to the position of the center of gravity G. The first bump group 4A3 and the second bump group 4B3 that are disposed parallel to the first active layer 21A are accordingly arranged on the bonding surface of the substrate-side electrode 12 such that the distance between the first bump group 4A3 and the first bonding surface 12A1 is longer than the distance between the second bump group 4B3 and the first bonding surface 12A1.

For example, in a case of the first active layer 21A, the distance between the first bump group 4A3 and the first bonding surface 12A1 is denoted by the distance A1, and the distance between the second bump group 4B3 and the first bonding surface 12A1 is denoted by the distance B1. Then, the first bump group 4A3 and the second bump group 4B3 are arranged on the bonding surface of the substrate-side electrode 12 so as to be parallel to the first active layer 21A such that the requirement of the distance A1>the distance B1 is satisfied.

The fourth bump group 4D3 arranged on the bonding surface of the substrate-side electrode 12 is defined as the bump group that is located at the position farther away from the position of the center of gravity G, and the third bump group 4C3 arranged on the bonding surface of the substrate-side electrode 12 is defined as the bump group that is located at the position closer to the position of the center of gravity G. The third bump group 4C3 and the fourth bump group 4D3 that are disposed parallel to the second active layer 51B are accordingly arranged on the bonding surface of the substrate-side electrode 12 such that the distance between the third bump group 4C3 and the second bonding surface 12A2 is longer than the distance between the fourth bump group 4D3 and the second bonding surface 12A2.

For example, in a case of the second active layer 21B, the distance between the fourth bump group 4D3 and the second bonding surface 12A2 is denoted by the distance A2, and the distance between the third bump group 4C3 and the second bonding surface 12A2 is denoted by the distance B2. Then, the third bump group 4C3 and the fourth bump group 4D3 are arranged on the bonding surface 12A of the substrate-side electrode 12 so as to be parallel to the second active layer 21B such that the requirement of the distance A2>the distance B2 is satisfied.

In the optical device 1D according to the fifth embodiment, the first bump group 4A3 and the second bump group 4B3 are arranged on the substrate-side electrode 12 such that the distance A1 between the first bump group 4A3 and the first bonding surface 12A1 is longer than the distance B1 between the second bump group 4B3 and the first bonding surface 12A1. Consequently, it is possible to ensure the heat dissipation characteristic by decreasing the distance B1 between the second bump group 4B3 and the first active layer 21A while suppressing the effect of the thermal stress by increasing the distance A1 between the first bump group 4A3 and the first active layer 21A.

In the optical device 1D, the third bump group 4C3 and the fourth bump group 4D3 are arranged on the substrate-side electrode 12 such that the distance A2 between the fourth bump group 4D3 and the second bonding surface 12A2 is longer than the distance B2 between the third bump group 4C3 and the second bonding surface 12A2. Consequently, it is possible to ensure the heat dissipation characteristic by decreasing the distance B2 between the third bump group 4C3 and the second active layer 21B while suppressing the effect of the thermal stress by increasing the distance A2 between the fourth bump group 4D3 and the second active layer 21B.

In addition, in the optical device 1D according to the fifth embodiment, a case has been described as an example in which a bump group is formed of the split bumps X each having the same size and the same arrangement interval; however, the bump group may be constituted of the split bumps X each having a different size or a different arrangement interval, and appropriate modifications are possible.

A case has been described as an example in which the first active layer 21A and the second active layer 21B each having a straight shape are built in the chip 3 included in the optical device 1A according to the second embodiment. However, an embodiment of an optical device that uses, for example, a U-turn type SOA for a compound semiconductor element and that allows one end of the first active layer 21A and one end of the second active layer 21B to be optically coupled to a U-shaped waveguide 23 will be described as a sixth embodiment. In addition, by assigning the same reference numerals to components having the same configuration as those in the optical device 1A according to the second embodiment, overlapped descriptions of the configuration and the operation thereof will be omitted.

### (f) Sixth Embodiment

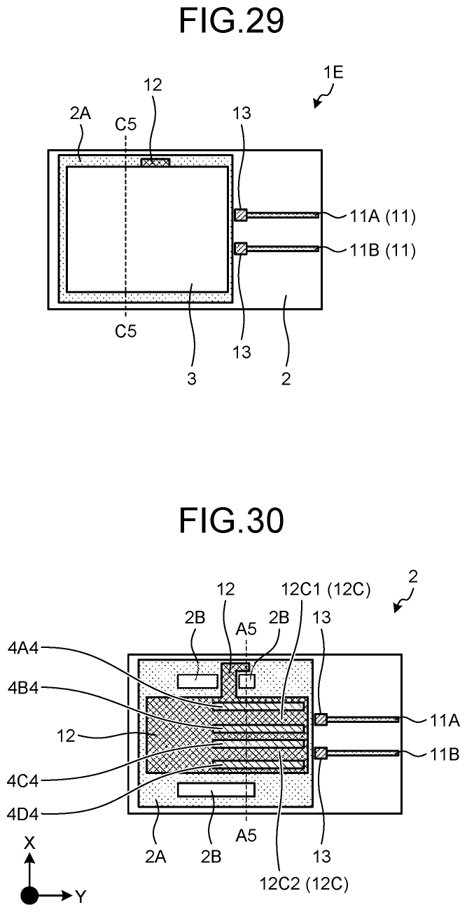

FIG. 29 is a schematic plan view illustrating an optical device 1E according to the sixth embodiment. The optical device 1E illustrated in FIG. 29 includes the substrate 2 that has the two built-in optical waveguides 11, and the chip 3 that has the two built-in active layers 21. Furthermore, the chip 3 includes, for example, a built-in and U-turn type semiconductor optical amplifier (SOA), and the U-shaped waveguide 23 that allows one end of the first active layer 21A to be optically coupled to one end of the second active layer 21B. The U-turn type SOA is constituted of a waveguide with an embedded type in which the side surfaces of a waveguide core layer is embedded by a semiconductor layer. In order to reduce the curvature radius of the U-shaped waveguide 23, a high mesa waveguide in which the side surfaces of the waveguide core are not embedded by a semiconductor and light is strongly confined is used for a U-turn portion disposed at a position in which the waveguide is returned. In addition, the active layer 21 included in the U-turn type SOA used here is constituted such that, for example, a light wavelength is 1.55 μm, and a mode diameter of an output end is 3 μm.

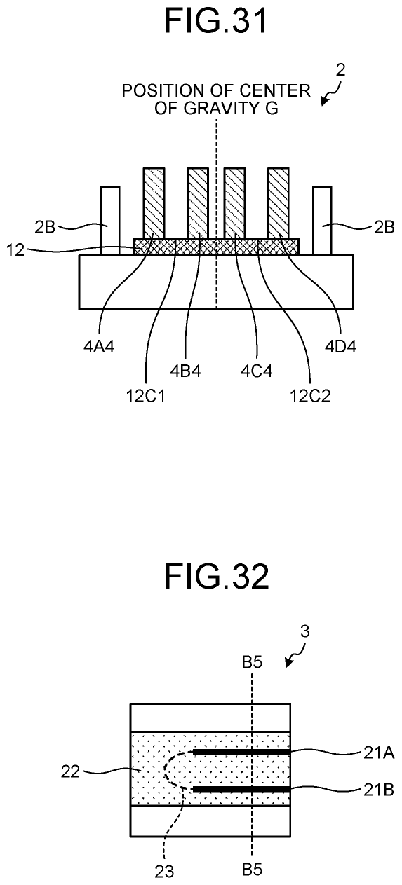

FIG. 30 is a schematic plan view illustrating an example of the substrate 2, and FIG. 31 is a schematic cross-sectional diagram of the substrate 2 taken along line A5-A5 illustrated in FIG. 30. The four solder bumps 4 are arranged on the bonding surface of the substrate-side electrode 12 illustrated in FIG. 30. The solder bumps 4 include a first bump 4A4, a second bump 4B4, a third bump 4C4, and a fourth bump 4D4.

The first bump 4A4 and the second bump 4B4 are arranged on only both sides of a first bonding surface 12C1 that is located opposite the first active layer 21A and that is included in a bonding surface 12C of the substrate-side electrode 12 bonded to the chip-side electrode 22. In addition, it is assumed that the first bump 4A4 and the second bump 4B4 are not arranged on the substrate-side electrode 12 that is located opposite the U-shaped waveguide 23 that is optically coupled the first active layer 21A.

The third bump 4C4 and the fourth bump 4D4 are arranged on both sides of a second bonding surface 12C2 that is located opposite the second active layer 21B and that is included in the bonding surface 12C of the substrate-side electrode 12 bonded to the chip-side electrode 22. In addition, it is assumed that the third bump 4C4 and the fourth bump 4D4 are not arranged on the substrate-side electrode 12 that is located opposite the U-shaped waveguide 23 that is optically coupled to the second active layer 21B.

The position of the center of gravity G illustrated in FIG. 31 is calculated by using the coordinates of the center of gravity of all of the solder bumps 4 arranged on the substrate-side electrode 12 included in the substrate 2. The position of the center of gravity G is accordingly used to determine the positions of the solder bumps 4 to be arranged on the bonding surface of the substrate-side electrode 12.

On the substrate 2, if the X-axis and the Y-axis are defined, an area of the first bump 4A4 that is located at a position farther away from the position of the center of gravity G between the solder bumps 4 that are located on both sides of the first bonding surface 12C1 that is located opposite the first active layer 21A is defined as S_{A1}, and the coordinates of the center of gravity of the first bump 4A4 are defined as (X_{A1}, Y_{A1}). Furthermore, an area of the second bump 4B4 that is located at a position closer to the position of the center of gravity G between the solder bumps 4 that are located on both sides of the first bonding surface 12C1 that is located opposite the first active layer 21A is defined as S_{B1}, and the coordinates of the center of gravity of the second bump 4B4 are defined as (X_{B1}, Y_{B1}). An area of the fourth bump 4D4 that is located at a position farther away from the position of the center of gravity G between the solder bump 4 that are located on both sides of the second bonding surface 12C2 that is located opposite the second active layer 21B is defined as S_{A2}, and the coordinates of the center of gravity of the fourth bump 4D4 are defined as (X_{A2}, Y_{A2}). Furthermore, an area of the third bump 4C4 that is located at a position closer to the position of the center of gravity G between the solder bumps 4 that are located on both sides of the second bonding surface 12C2 that is located opposite the second active layer 21B is defined as S_{B2}, and the coordinates of the center of gravity of the third bump 4C4 are defined as (X_{B2}, Y_{B2}). The coordinates (X_{G}, Y_{G}) of the position of the center of gravity G of all of the solder bumps 4 are calculated on the basis of the coordinates of the center of gravity and the area of each of the first bump 4A4, the second bump 4B4, the third bump 4C4, and the fourth bump 4D4.

At the first bump 4A4 located at the position farther away from the position of the center of gravity G, thermal stress produced caused by a difference between the thermal expansion coefficients of the chip 3 and the substrate 2 is large, and, in contrast, at the second bump 4B4 located at the position closer to the position of the center of gravity G, thermal stress is small. The effect of the thermal stress is suppressed by increasing the distance between the first bump 4A4 located at the position farther away from the position of the center of gravity G and the first active layer 21A, and a heat dissipation characteristic can be ensured by decreasing the distance between the second bump 4B4 located at the position closer to the position of the center of gravity G and the first active layer 21A. At the fourth bump 4D4 located at the position farther away from the position of the center of gravity G, thermal stress produced caused by a difference between the thermal expansion coefficients of the chip 3 and the substrate 2 is large, and, in contrast, at the third bump 4C4 located at the position closer to the position of the center of gravity G, thermal stress is small. The effect of the thermal stress is suppressed by increasing the distance between the fourth bump 4D4 located at the position farther away from the position of the center of gravity G, and a heat dissipation characteristic can be ensured by decreasing the distance between the third bump 4C4 located at the position closer to the position of the center of gravity G and the second active layer 21B.

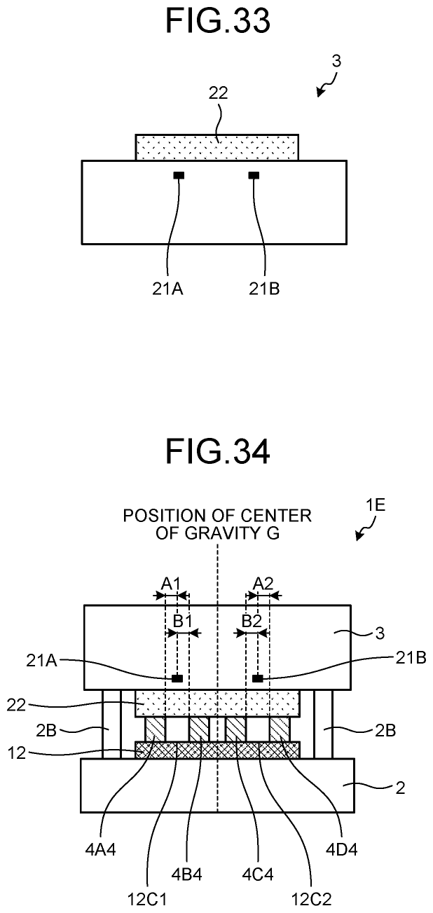

FIG. 32 is a schematic plan view illustrating an example of the chip 3, and FIG. 33 is a schematic cross-sectional diagram of the chip 3 taken along line B5-B5 illustrated in FIG. 32. The U-shaped waveguide 23 included in the chip 3 illustrated in FIG. 32 is a waveguide that allows one end of the first active layer 21A to be optically coupled to one end of the second active layer 21B.

The chip-side electrode 22 is bonded to and mounted on the bonding surface of the substrate-side electrode 12 via the solder bump 4. When the chip 3 is mounted on the substrate 2, the first active layer 21A included in the chip 3 is optically coupled to the first optical waveguide 11A that is disposed on the substrate 2, and the second active layer 21B is accordingly optically coupled to the second optical waveguide 11B that is disposed on the substrate 2.

FIG. 34 is a schematic cross-sectional diagram taken along line C5-C5 illustrated in FIG. 29. The first bump 4A4 arranged on the bonding surface of the substrate-side electrode 12 illustrated in FIG. 34 is defined as the solder bump 4 that is located at the position farther away from the position of the center of gravity G of all of the solder bumps 4, and the second bump 4B4 arranged on the bonding surface of the substrate-side electrode 12 is defined as the solder bump 4 that is located at the position closer to the position of the center of gravity G. The first bump 4A4 and the second bump 4B4 that are disposed parallel to the first active layer 21A are arranged on the bonding surface of the substrate-side electrode 12 such that the distance between the first bump 4A4 and the first bonding surface 12C1 is longer than the distance between the second bump 4B4 and the first bonding surface 12C1.

For example, in a case of the first active layer 21A, the distance between the first bump 4A4 and the first bonding surface 12C1 is denoted by the distance A1, and the distance between the second bump 4B4 and the first bonding surface 12C1 is denoted by the distance B1. Then, the first bump 4A4 and the second bump 4B4 are arranged on the bonding surface of the substrate-side electrode 12 so as to be parallel to the first active layer 21A such that the requirement of the distance A1>the distance B1 is satisfied.

The fourth bump 4D4 arranged on the bonding surface of the substrate-side electrode 12 is defined as the solder bump 4 that is located at the position farther away from the position of the center of gravity G, and the third bump 4C4 arranged on the bonding surface of the substrate-side electrode 12 is defined as the solder bump 4 that is located at the position closer to the position of the center of gravity G. The third bump 4C4 and the fourth bump 4D4 that are disposed parallel to the second active layer 21B are arranged on the bonding surface of the substrate-side electrode 12 such that the distance between the third bump 4C4 and the second bonding surface 12C2 is longer than the distance between the fourth bump 4D4 and the second bonding surface 12C2.

For example, in a case of the second active layer 21B, the distance between the fourth bump 4D4 and the second bonding surface 12C2 is denoted by the distance A2, and the distance between the third bump 4C4 and the second bonding surface 12C2 is denoted by the distance B2. Then, the third bump 4C4 and the fourth bump 4D4 are arranged on the bonding surface of the substrate-side electrode 12 so as to be parallel to the second active layer 21B such that the requirement of the distance A2>the distance B2 is satisfied.

In the optical device 1E according to the sixth embodiment, the first bump 4A4 and the second bump 4B4 are arranged on the substrate-side electrode 12 such that the distance A1 between the first bump 4A4 and the first bonding surface 12C1 is longer than the distance B1 between the second bump 4B4 and the first bonding surface 12C1. Consequently, it is possible to ensure the heat dissipation characteristic by decreasing the distance B1 between the second bump 4B4 and the first active layer 21A while suppressing the effect of the thermal stress by increasing the distance A1 between the first bump 4A4 and the first active layer 21A.

In the optical device 1E, the third bump 4C4 and the fourth bump 4D4 are arranged on the substrate-side electrode 12 such that the distance A2 between the fourth bump 4D4 and the second bonding surface 12C2 is longer than the distance B2 between the third bump 4C4 and the second bonding surface 12C2. Consequently, it is possible to ensure the heat dissipation characteristic by decreasing the distance B2 between the third bump 4C4 and the second active layer 21B while suppressing the effect of the thermal stress by increasing the distance A2 between the fourth bump 4D4 and the second active layer 21B.

In addition, a case has been described as an example in which the chip 3 included in the optical device 1A according to the second embodiment has the two built-in active layers 21; however, the number of active layers 21 is not limited to two as long as one or more of the active layers 21 are used, and appropriate modifications are possible. An embodiment of an optical device 1F that allows the four active layers 21 to be optically coupled to the four optical waveguides 11 will be described as a seventh embodiment. In addition, by assigning the same reference numerals to components having the same configuration as those in the optical device 1A according to the second embodiment, overlapped descriptions of the configuration and the operation thereof will be omitted.

### (g) Seventh Embodiment

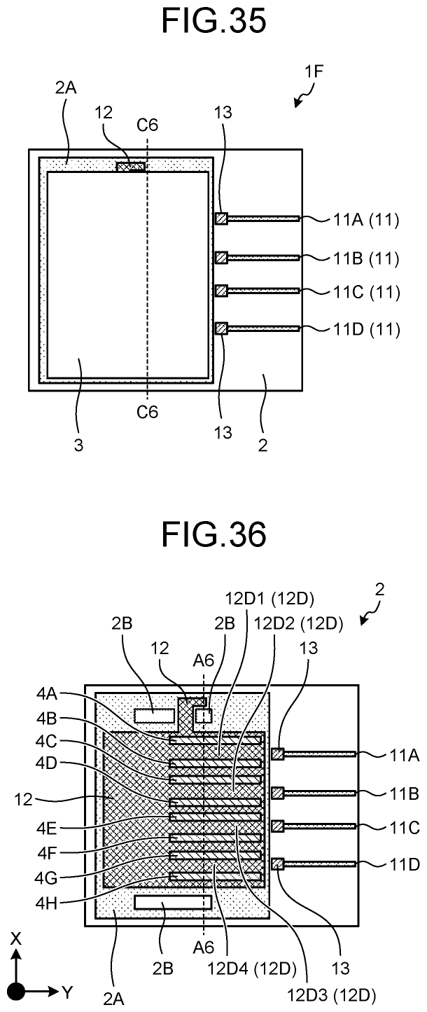

FIG. 35 is a schematic plan view illustrating an example of an optical device 1F according to the seventh embodiment. The optical device 1F illustrated in FIG. 36 includes the substrate 2 that has the four built-in optical waveguides 11, and the chip 3 that has the four built-in active layers 21, and the two built-in U-shaped waveguides 23. The four optical waveguides 11 include the first optical waveguide 11A, the second optical waveguide 11B, a third optical waveguide 11C, and a fourth optical waveguide 11D. The four active layers 21 include the first active layer 21A that is optically coupled to the first optical waveguide 11A, the second active layer 21B that is optically coupled to the second optical waveguide 11B, a third active layer 21C that is optically coupled to the third optical waveguide 11C, and a fourth active layer 21D that is optically coupled to the fourth optical waveguide 11D.

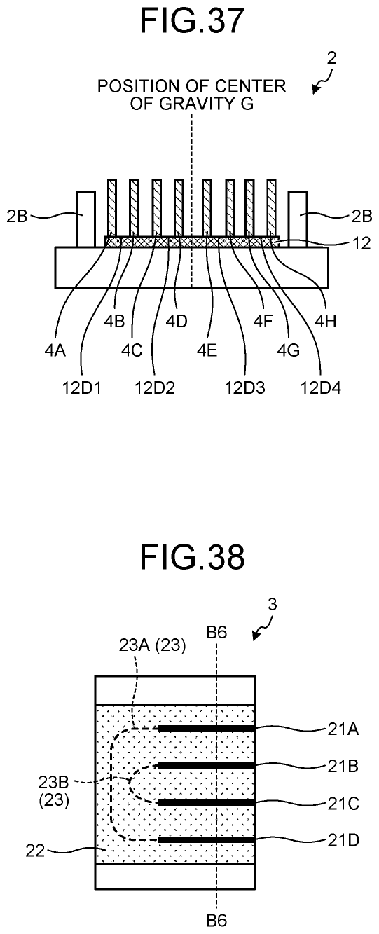

FIG. 36 is a schematic plan view illustrating an example of the substrate 2, and FIG. 37 is a schematic cross-sectional diagram of the substrate 2 taken along line A6-A6 illustrated in FIG. 36. The eight solder bumps 4 are arranged on the bonding surface of the substrate-side electrode 12 included in the substrate 2 illustrated in FIG. 36. The solder bump 4 includes the first bump 4A, the second bump 4B, a third bump 4C, a fourth bump 4D, a fifth bump 4E, a sixth bump 4F, a seventh bump 4G, and an eighth bump 4H.

The first bump 4A and the second bump 4B are arranged on both sides of a first bonding surface 12D1 that is located opposite the first active layer 21A and that is included in a bonding surface 12D of the substrate-side electrode 12 bonded to the chip-side electrode 22. The third bump 4C and the fourth bump 4D are arranged on both sides of a second bonding surface 12D2 that is located opposite the second active layer 21B and that is included in the bonding surface 12D of the substrate-side electrode 12 bonded to the chip-side electrode 22.

The fifth bump 4E and the sixth bump 4F are arranged on both sides of a third bonding surface 12D3 that is located opposite the third active layer 21C and that is included in the bonding surface 12D of the substrate-side electrode 12 bonded to the chip-side electrode 22. The seventh bump 4G and the eighth bump 4H are arranged on both sides of a fourth bonding surface 12D4 that is located opposite the fourth active layer 21D and that is included in the bonding surface 12D of the substrate-side electrode 12 bonded to the chip-side electrode 22.

The position of the center of gravity G illustrated in FIG. 37 is calculated by using the coordinates of the center of gravity of all of the solder bumps 4 arranged on the substrate-side electrode 12 included in the substrate 2. The position of the center of gravity G is accordingly used to determine the positions of the solder bumps 4 to be arranged on the bonding surface of the substrate-side electrode 12.

On the substrate 2, if the X-axis and the Y-axis are defined, an area of the first bump 4A that is located at a position farther away from the position of the center of gravity G between the solder bumps 4 that are located on both sides of the first bonding surface 12D1 that is located opposite the first active layer 21A is defined as S_{A1}, and the coordinates of the center of gravity of the first bump 4A are defined as (X_{A1}, Y_{A1}). Furthermore, an area of the second bump 4B that is located at a position closer to the position of the center of gravity G between the solder bumps 4 that are located on both sides of the first bonding surface 12D1 that is located opposite the first active layer 21A is defined as S_{B1}, and the coordinates of the center of gravity of the second bump 4B are defined as (X_{B1}, Y_{B1}). An area of the third bump 4C that is located at a position farther away from the position of the center of gravity G between the solder bumps 4 that are located on both sides of the second bonding surface 12D2 that is located opposite the second active layer 21B is defined as S_{A2}, and the coordinates of the center of gravity of the third bump 4C are defined as (X_{A2}, Y_{A2}). Furthermore, an area of the fourth bump 4D that is located at a position closer to the position of the center of gravity G between the solder bumps 4 that are located on both sides of the second bonding surface 12D2 that is located opposite the second active layer 21B is defined as S_{B2}, and the coordinates of the center of gravity of the fourth bump 4D are defined as (X_{B2}, Y_{B2}).

An area of the sixth bump 4F that is located at a position farther away from the position of the center of gravity G between the solder bumps 4 that are located on both sides of the third bonding surface 12D3 that is located opposite the third active layer 21C is defined as S_{A3}, and the coordinates of the center of gravity of the sixth bump 4F are defined as (X_{A3}, Y_{A3}). Furthermore, an area of the fifth bump 4E that is located at a position closer to the position of the center of gravity G between the solder bumps 4 that are located on both sides of the third bonding surface 12D3 that is located opposite the third active layer 21C is defined as S_{B3}, and the coordinates of the center of gravity of the fifth bump 4E are defined as (X_{B3}, Y_{B3}). An area of the eighth bump 4H that is located at a position farther away from the position of the center of gravity G between the solder bumps 4 that are located on both sides of the fourth bonding surface 12D4 that is located opposite the fourth active layer 21D is defined as S_{A4}, and the coordinates of the center of gravity of the eighth bump 4H are defined as (X_{A4}, Y_{A4}). Furthermore, an area of the seventh bump 4G that is located at a position closer to the position of the center of gravity G between the solder bumps 4 that are located on both sides of the fourth bonding surface 12D4 that is located opposite the fourth active layer 21D is defined as S_{B4}, and the coordinates of the center of gravity of the seventh bump 4G are defined as (X_{B4}, Y_{B4}). The coordinates (X_{G}, Y_{G}) of the position of the center of gravity G of all of the solder bumps 4 are calculated on the basis of the coordinates of the center of gravity and the area of each of the first bump 4A, the second bump 4B, the third bump 4C, the fourth bump 4D, the fifth bump 4E, the sixth bump 4F, the seventh bump 4G, and the eighth bump 4H.

At the first bump 4A located at the position farther away from the position of the center of gravity G, thermal stress produced caused by a difference between the thermal expansion coefficients of the chip 3 and the substrate 2 is large, and, in contrast, at the second bump 4B located at the position closer to the position of the center of gravity G, thermal stress is small. The effect of the thermal stress is suppressed by increasing the distance between the first bump 4A located at the position farther away from the position of the center of gravity G and the first active layer 21A, and a heat dissipation characteristic can be ensured by decreasing the distance between the second bump 4B located at the position closer to the position of the center of gravity G and the first active layer 21A. At the third bump 4C located at the position farther away from the position of the center of gravity G, thermal stress produced caused by a difference between the thermal expansion coefficients of the chip 3 and the substrate 2 is large, and, in contrast, at the fourth bump 4D located at the position closer to the position of the center of gravity G, thermal stress is small. The effect of the thermal stress is suppressed by increasing the distance between the third bump 4C located at the position farther away from the position of the center of gravity G and the second active layer 21B, and a heat dissipation characteristic can be ensured by decreasing the distance between the fourth bump 4D located at the position closer to the position of the center of gravity G and the second active layer 21B.

At the sixth bump 4F located at the position farther away from the position of the center of gravity G, thermal stress produced caused by a difference between the thermal expansion coefficients of the chip 3 and the substrate 2 is large, and, in contrast, at the fifth bump 4E located at the position closer to the position of the center of gravity G, thermal stress is small. The effect of the thermal stress is suppressed by increasing the distance between the sixth bump 4F located at the position farther away from the position of the center of gravity G and the third active layer 21C, and a heat dissipation characteristic can be ensured by decreasing the distance between the fifth bump 4E located at the position closer to the position of the center of gravity G. At the eighth bump 4H located at the position farther away from the position of the center of gravity G, thermal stress produced caused by a difference between the thermal expansion coefficients of the chip 3 and the substrate 2 is large, and, in contrast, at the seventh bump 4G located at the position closer to the position of the center of gravity G, thermal stress is small. The effect of the thermal stress is suppressed by increasing the distance between the eighth bump 4H located at the position farther away from the position of the center of gravity G and the fourth active layer 21D, and a heat dissipation characteristic can be ensured by decreasing the distance between the seventh bump 4G located at the position closer to the position of the center of gravity G and the fourth active layer 21D.

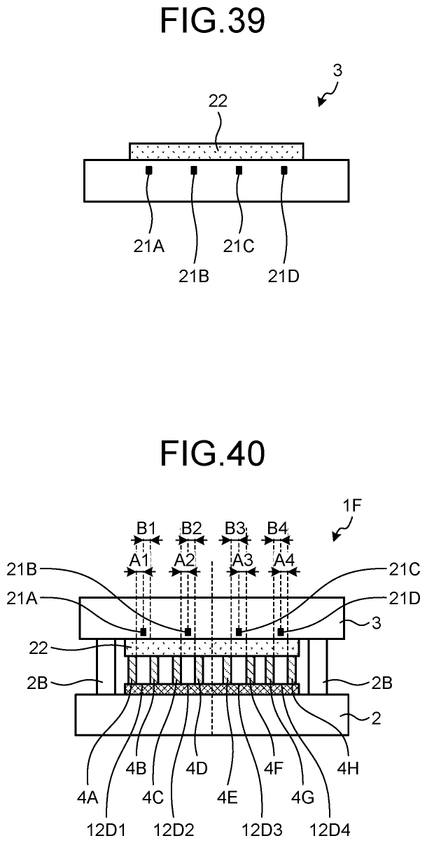

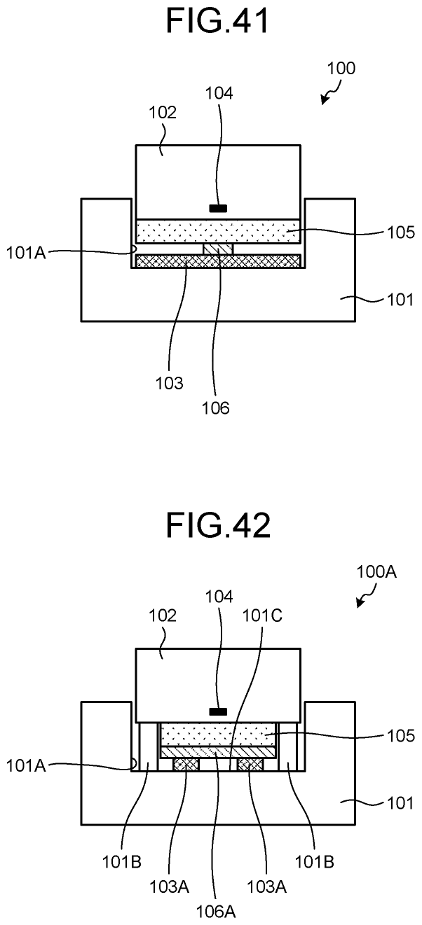

FIG. 38 is a schematic plan view illustrating an example of the chip 3, and FIG. 39 is a schematic cross-sectional diagram of the chip 3 taken along line B6-B6 illustrated in FIG. 38. The chip-side electrode 22 included in the chip 3 illustrated in FIG. 38 is bonded on the bonding surface of the substrate-side electrode 12 via the solder bump 4. When the chip 3 is mounted on the substrate 2, the first active layer 21A included in the chip 3 is accordingly optically coupled to the first optical waveguide 11A that is disposed on the substrate 2, and the second active layer 21B is accordingly optically coupled to the second optical waveguide 11B that is disposed on the substrate 2. When the chip 3 is mounted on the substrate 2, the third active layer 21C included in the chip 3 is accordingly optically coupled to the third optical waveguide 11C that is disposed on the substrate 2, and the fourth active layer 21D is accordingly optically coupled to the fourth optical waveguide 11D that is disposed on the substrate 2.

The two U-shaped waveguides 23 include a first U-shaped waveguide 23A and a second U-shaped waveguide 23B. The first U-shaped waveguide 23A is a waveguide that allows the first active layer 21A to be optically coupled to the fourth active layer 21D. The second U-shaped waveguide 23B is a waveguide that allows the second active layer 21B to be optically coupled to the third active layer 21C.

FIG. 40 is a schematic cross-sectional diagram taken along line C6-C6 illustrated in FIG. 35. The first bump 4A arranged on the bonding surface of the substrate-side electrode 12 illustrated in FIG. 40 is defined as the solder bump 4 that is located at the position farther away from the position of the center of gravity G of all of the solder bumps 4, and the second bump 4B arranged on the bonding surface of the substrate-side electrode 12 is defined as the solder bump 4 that is located at the position closer to the position of the center of gravity G. The first bump 4A and the second bump 4B that are disposed parallel to the first active layer 21A are arranged on the bonding surface 12D such that the distance between the first bump 4A and the first bonding surface 12D1 is longer than the distance between the second bump 4B and the first bonding surface 12D1.

For example, in a case of the first active layer 21A, the distance between the first bump 4A and the first bonding surface 12D1 is denoted by the distance A1, and the distance between the second bump 4B and the first bonding surface 12D1 is denoted by the distance B1. Then, the first bump 4A and the second bump 4B are arranged on the bonding surface of the substrate-side electrode 12 so as to be parallel to the first active layer 21A such that the requirement of the distance A1>the distance B1 is satisfied.

For example, in a case of the second active layer 21B, the distance between the third bump 4C and the second bonding surface 12D2 is denoted by the distance A2, and the distance between the fourth bump 4D and the second bonding surface 12D2 is denoted by the distance B2. Then, the third bump 4C and the fourth bump 4D are arranged on the bonding surface of the substrate-side electrode 12 to as to be parallel to the second active layer 21B such that the requirement of the distance A2>the distance B2 is satisfied.

For example, in a case of the third active layer 21C, the distance between the sixth bump 4F and the third bonding surface 12D3 is denoted by a distance A3, and the distance between the fifth bump 4E and the third bonding surface 12D3 is denoted by a distance B3. Then, the fifth bump 4E and the sixth bump 4F are arranged on the bonding surface of the substrate-side electrode 12 so as to be parallel to the third active layer 21C such that the requirement of the distance A3>the distance B3 is satisfied.

For example, in a case of the fourth active layer 21D, the distance between the eighth bump 4H and the fourth bonding surface 12D4 is denoted by a distance A4, and the distance between the seventh bump 4G and the fourth bonding surface 12D4 is denoted by a distance B4. Then, the seventh bump 4G and the eighth bump 4H are arranged on the bonding surface of the substrate-side electrode 12 so as to be parallel to the fourth active layer 21D such that the requirement of the distance A4>the distance B4 is satisfied.

In the optical device 1F according to the seventh embodiment, the first bump 4A and the second bump 4B are arranged on the substrate-side electrode 12 such that the distance A1 between the first bump 4A and the first bonding surface 12D1 is longer than the distance B1 between the second bump 4B and the first bonding surface 12D1. Consequently, it is possible to ensure the heat dissipation characteristic by decreasing the distance B1 between the second bump 4B and the first active layer 21A while suppressing the effect of the thermal stress by increasing the distance A1 between the first bump 4A and the first active layer 21A.

In the optical device 1F, the third bump 4C and the fourth bump 4D are arranged on the substrate-side electrode 12 such that the distance A2 between the third bump 4C and the second bonding surface 12D2 is longer than the distance B2 between the fourth bump 4D and the second bonding surface 12D2. Consequently, it is possible to ensure the heat dissipation characteristic by decreasing the distance B2 between the fourth bump 4D and the second active layer 21B while suppressing the effect of the thermal stress by increasing the distance A2 between the third bump 4C and the second active layer 21B.

In the optical device 1F, the fifth bump 4E and the sixth bump 4F are arranged on the substrate-side electrode 12 such that the distance A3 between the sixth bump 4F and the third bonding surface 12D3 is longer than the distance B3 between the fifth bump 4E and the third bonding surface 12D3. Consequently, it is possible to ensure the heat dissipation characteristic by decreasing the distance B3 between the fifth bump 4E and the third active layer 21C while suppressing the effect of the thermal stress by increasing the distance A3 between the sixth bump 4F and the third active layer 21C.

In the optical device 1F, the seventh bump 4G and the eighth bump 4H are arranged on the substrate-side electrode 12 such that the distance A4 between the eighth bump 4H and the fourth bonding surface 12D4 is longer than the distance B4 between the seventh bump 4G and the fourth bonding surface 12D4. Consequently, it is possible to ensure the heat dissipation characteristic by decreasing the distance B4 between the seventh bump 4G and the fourth active layer 21D while suppressing the effect of the thermal stress by increasing the distance A4 between the eighth bump 4H and the fourth active layer 21D.

In addition, a case has been described as an example in which an InP-based compound semiconductor is used for the compound semiconductor element included in the optical device 1 according to the present embodiment; however, the example is not limited to this. For example, a GaAs-based compound semiconductor may be used, and appropriate modifications are possible.

A case has been described as an example in which, in the optical device 1 according to the first to the sixth embodiments, the arrangement structure of the solder bump 4 is constituted to have the distance A1=the distance A2=75 μm, and the distance B1=the distance B2=25 μm. However, any arrangement structure may be used as long as a requirement of the distance A_{N}>the distance B_{N} is satisfied, and appropriate modifications are possible. As an arrangement interval of the solder bump 4, for example, the distance A1≠the distance A2, and the distance B1≠the distance B2 may be used, and appropriate modifications are possible.

A case has been described in which an AuSn bump is used for the solder bumps 4 that are used in the optical device 1; however, the example is not limited to this. For example, AuSi, AuGe, SnAg, or SnAgCu may be used for the solder bumps 4, and appropriate modifications are possible.

According to an aspect of an embodiment of the optical device, and the like disclosed in the present invention, it is possible to ensure a heat dissipation characteristic while suppressing the effect of thermal stress.

All examples and conditional language recited herein are intended for pedagogical purposes of aiding the reader in understanding the invention and the concepts contributed by the inventor to further the art, and are not to be construed as limitations to such specifically recited examples and conditions, nor does the organization of such examples in the specification relate to a showing of the superiority and inferiority of the invention. Although the embodiments of the present invention have been described in detail, it should be understood that the various changes, substitutions, and alterations could be made hereto without departing from the spirit and scope of the invention.

What is claimed is:

1. An optical device comprising:
a substrate that includes a substrate-side electrode; and
a chip that includes N (N≥1) active layers with a stripe shape and a chip-side electrode that is mounted on the substrate-side electrode, wherein
from among bumps that are disposed side by side with an Nth active layer on both sides of a bonding surface that is located opposite the Nth active layer and that is included in the substrate-side electrode,
bumps located at a position farther away from a position of the center of gravity of all of the bumps are defined as first bumps, and
bumps located at a position closer to the position of the center of gravity are defined as second bumps, and
in at least one combination of the first bump and the second bump, the first bump and the second bump are arranged on the substrate-side electrode such that a distance between the first bump and the bonding surface is longer than a distance between the second bump and the bonding surface.

2. An optical device comprising:
a substrate that includes a substrate-side electrode; and
a chip that includes a first active layer with a stripe shape, a second active layer that is disposed side by side with the first active layer, and a chip-side electrode that is mounted on the substrate-side electrode, wherein
between bumps that are disposed side by side with the first active layer on both sides of a first bonding surface that is located opposite the first active layer and that is included in the substrate-side electrode,
a bump located at a position farther away from a position of the center of gravity of all of the bumps is defined as a first bump, and
a bump located at a position closer to the position of the center of gravity is defined as a second bump,
the first bump and the second bump are arranged on the substrate-side electrode such that a distance between the first bump and the first bonding surface is longer than a distance between the second bump and the first bonding surface,
between bumps that are disposed side by side with the second active layer on both sides of a second bonding surface that is located opposite the second active layer and that is included in the substrate-side electrode,
a bump located at a position farther away from the position of the center of gravity is defined as a fourth bump, and
a bump located at a position closer to the position of the center of gravity is defined as a third bump, and
the third bump and the fourth bump are arranged on the substrate-side electrode such that a distance between the fourth bump and the second bonding surface is longer than a distance between the third bump and the second bonding surface.

3. The optical device according to claim 2, wherein the first bump, the second bump, the third bump, and the fourth bump are arranged in parallel in a stripe shaped manner on the substrate-side electrode.

4. The optical device according to claim 3, wherein
a single fifth bump is used instead of the second bump and the third bump,
between bumps that are disposed side by side with the first active layer on both sides of the first bonding surface that is located opposite the first active layer and that is included in the substrate-side electrode,
a bump located at a position farther away from the position of the center of gravity is defined as the first bump, and
a bump located at a position closer to the position of the center of gravity is defined as the fifth bump,
the first bump and the fifth bump are arranged on the substrate-side electrode such that the distance between the first bump and the first bonding surface is longer than a distance between the fifth bump and the first bonding surface,
between bumps that are disposed side by side with the second active layer on both sides of the second bonding surface that is located opposite the second active layer and that is included in the substrate-side electrode,
a bump located at a position farther away from the position of the center of gravity is defined as the fourth bump, and
a bump located at a position closer to the position of the center of gravity is defined as the fifth bump, and
the fifth bump and the fourth bump are arranged on the substrate-side electrode such that the distance between the fourth bump and the second bonding surface is longer than a distance between the fifth bump and the second bonding surface.

5. The optical device according to claim 2, wherein the first bump, the second bump, the third bump, and the fourth bump are constituted by arraying a plurality of split bumps in a linear manner.

6. The optical device according to claim 2, wherein the chip includes a U-shaped waveguide that allows one end of the first active layer to be optically coupled to one end of the second active layer.

7. The optical device according to claim 2, wherein
the substrate includes a first waveguide and a second waveguide, and
in a case where the chip-side electrode is mounted on the substrate-side electrode, the first waveguide is allowed to be optically coupled to the first active layer that is included in the chip, and the second waveguide is allowed to be optically coupled to the second active layer that is included in the chip.

8. A bump arrangement method performed in an optical device that includes
a substrate that includes a substrate-side electrode; and
a chip that includes N (N≥1) active layers with a stripe shape and a chip-side electrode that is mounted on the substrate-side electrode, the bump arrangement method comprising:
from among bumps that are disposed side by side with an Nth active layer on both sides of a bonding surface that is located opposite the Nth active layer and that is included in the substrate-side electrode,
defining bumps located at a position farther away from a position of the center of gravity of all of the bumps as first bumps, and defining bumps located at a position closer to the position of the center of gravity as second bumps, and
arranging the first bump and the second bump on the substrate-side electrode such that, in at least one combination of the first bump and the second bump, a distance between the first bump and the bonding surface is longer than a distance between the second bump and the bonding surface.
